(19) United States
(12) Patent Application Publication
(10) Pub. No.: US 2025/0311203 A1
(43) Pub. Date: Oct. 2, 2025

(54) HETEROGENEOUS MEMORY STACK WITH SHARED LOGIC CIRCUIT

(71) Applicant: Intel Corporation, Santa Clara, CA (US)

(72) Inventors: Abhishek A. Sharma, Portland, OR (US); Wilfred Gomes, Portland, OR (US)

(73) Assignee: Intel Corporation, Santa Clara, CA (US)

(21) Appl. No.: 18/618,128

(22) Filed: Mar. 27, 2024

(51) Int. Cl. H10B 12/00; H10B 10/00

(52) U.S. Cl. CPC H10B 12/50; H10B 10/125; H10B 10/18; H10B 12/315

(57) ABSTRACT

A heterogeneous memory stack may include two or more memory layers with different conductor pitches. The memory layers may share the same logic circuit, which may be a periphery circuit. The heterogeneous memory stack may include a SRAM layer and a DRAM layer as an example. As another example, the heterogeneous memory stack may include a DRAM layer and another DRAM layer. The logic circuit may be in a layer that is over the memory layers. The logic layer may be between a device region (e.g., a Si substrate) and a memory layer. The logic circuit may include sense amplifier and wordline drivers. A sense amplifier may be coupled to bitlines in multiple memory layers. The cross-layer connection may be facilitated using a multiplexer. The multiplex ratio of the multiplexer may be the same as the ratio of conductor pitches of different memory layers in the heterogeneous memory stack.

### BACKGROUND

Integrated circuit (IC) fabrication usually includes two stages. The first stage is referred to as the front end of line (FEOL). The second stage is referred to as the back end of line (BEOL). In the FEOL, individual semiconductor devices components (e.g., transistor, capacitors, resistors, etc.) can be patterned on a wafer. The FEOL stage may include a complementary metal-oxide-semiconductor (CMOS) process, in which metal-oxide-semiconductor field-effect transistors (MOSFETs) (such as symmetrical pairs of P-type and N-type MOSFETs) can be fabricated. In the BEOL, metal layers, vias, and insulating layers can be formed to get the individual components interconnected. The BEOL usually starts with forming the first metal layer on the wafer. The first metal layer is often called M0. More metal layers can be formed on top of M0, and these metal layers are often called M1, M2, and so on.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 illustrates an example IC device including a heterogeneous memory stack with a shared logic circuit, according to some embodiments of the disclosure.

FIG. 2 illustrates another example IC device including a heterogeneous memory stack with a shared logic circuit, according to some embodiments of the disclosure.

FIG. 3 illustrates electrical connections in a heterogeneous memory stack, according to some embodiments of the disclosure.

FIG. 4 illustrates cross-layer connections in a heterogeneous memory stack, according to some embodiments of the disclosure.

FIG. 5 is an electric circuit diagram of a heterogeneous memory stack with multiplexers for cross-layer connection, according to some embodiments of the disclosure.

FIG. 6 is a cross-sectional view of a heterogeneous memory stack, according to some embodiments of the disclosure.

FIG. 7A shows an example transistor with a fin, according to some embodiments of the disclosure.

FIG. 7B shows an example transistor with nanoribbons, according to some embodiments of the disclosure.

FIG. 8A illustrates semiconductor regions of a transistor in a memory layer, according to some embodiments of the disclosure.

FIG. 8B illustrates semiconductor regions of a transistor in a logic layer, according to some embodiments of the disclosure.

FIG. 9A is an electric circuit diagram of an example memory cell, according to some embodiments of the present disclosure.

FIG. 9B provides a top-down plan view of one example implementation of the memory cell, according to some embodiments of the present disclosure.

FIG. 10 is an electric circuit diagram of a memory array, according to some embodiments of the present disclosure.

FIGS. 11A-11B are top views of a wafer and dies that may include one or more heterogeneous memory stacks with shared logic circuits, according to some embodiments of the disclosure.

FIG. 12 is a side, cross-sectional view of an example IC package that may include one or more IC devices having heterogeneous memory stacks with shared logic circuits, according to some embodiments of the disclosure.

FIG. 13 is a cross-sectional side view of an IC device assembly that may include components having heterogeneous memory stacks with shared logic circuits, according to some embodiments of the disclosure.

FIG. 14 is a block diagram of an example computing device that may include one or more components with heterogeneous memory stacks with shared logic circuits, according to some embodiments of the disclosure.

FIG. 15 is a block diagram of an example processing device that may include one or more heterogeneous memory stacks with shared logic circuits, according to some embodiments of the disclosure.

### DETAILED DESCRIPTION

The systems, methods, and devices of this disclosure each have several innovative aspects, no single one of which is solely responsible for all of the desirable attributes disclosed herein. Details of one or more implementations of the subject matter described in this specification are set forth in the description below and the accompanying drawings.

Embodiments of the present disclosure are applicable to different types of memory devices. Some embodiments of the present disclosure may refer to static random-access memory (SRAM). Other embodiments of the present disclosure may refer to dynamic random-access memory (DRAM). However, embodiments of the present disclosure may be equally applicable to memory cells implemented other technologies. Thus, in general, memory cells/arrays described herein may be implemented as standalone SRAM devices, DRAM devices, or any other volatile or nonvolatile memory cells/arrays. A memory device usually includes a plurality of memory cells. A memory cell includes a memory element, which stores information, and an access transistor, which is coupled to the memory element and controls access to the memory element. Memory cells have, conventionally, been implemented with access transistors being FEOL, logic-process based, transistors implemented in an upper-most layer of a semiconductor substrate.

A memory cell may be a fundamental building block of computer memory devices used to store and retrieve data. It may be a small unit of storage that can hold a single bit of information, which can be either a 0 or a 1. Memory cells may be organized in a grid-like structure to form memory arrays. A memory cell may include a memory element, which stores information, and an access transistor, which is coupled to the memory element and controls access to the memory element. A memory device may also include bitlines and wordlines coupled to memory cells. A bitline can couple the memory cells in the memory array to the memory control circuitry. A bitline can be used for reading and writing data. A wordline can be used to control the access to a specific row of memory cells in the memory array. When the word line is activated, it enables the data stored in the selected row to be read or modified.

Currently available memory devices usually have separate logic circuits for different memory layers. A logic circuit usually includes one or more sense amplifiers, one or more wordline drivers, or other components that control memory cells. A logic circuit may include one or more CMOS circuits. Logic circuits may be referred to as a periphery circuit. Fabrication of logic circuits typically requires CMOS processes. However, CMOS processes are not always cost efficient. The cost of manufacturing these memory layers can be high. Therefore, improved technologies for fabricating memory layers are needed.

Embodiments of the present disclosure may improve on at least some of the challenges and issues described above by providing heterogeneous memory stacks with shared logic circuits. An example heterogeneous memory stack may include two or more memory layers with different conductor pitches (also referred to as “pitch”). A conductor pitch of a memory layer may be the distance between two adjacent conductive structures in the memory layer. The distance may be a center-to-center distance. The conductor pitches may be in a range from approximately 35 nanometers to approximately 300 nanometers. The ratio between two different conductive pitches in the heterogeneous memory stack may be in a range from approximately 1.25 to approximately 4. The conductive structures may be conductive lines, transistor electrodes, via, capacitors, or other types of conductive structures. A conductive line may be an interconnect (e.g., a metal line in a metal layer) or a control line (e.g., bitline, wordline, etc.) in the memory layer. In some embodiments, the heterogeneous memory stack may include at least one layer of SRAM cells stacked over at least one layer of DRAM cells. The SRAM layer may have a larger conductor pitch than the DRAM layer. In other embodiments, the heterogeneous memory stack may include two or more DRAM layers with different pitches stacked together. Memory layers of different pitches may share the same logic layer. The logic layer may include one or more logic circuits, which may be periphery circuits. The logic layer may be between the memory layers and a device region, which may be a silicon (Si) substrate.

In various embodiments, the logic layer may include one or more sense amplifiers and one or more wordline drivers. The sense amplifiers may be coupled to bitlines in the memory layers. The wordline drivers may be coupled to wordlines in the memory layers. In some embodiments, a sense amplifier may be coupled to bitlines in multiple memory layers. The electrical connections between the sense amplifier and the bitlines cross at least one memory layer. The electrical connections may be facilitated by vias extending from the logic layer to a memory layer. The cross-layer connection may include a multiplexer. The multiplexer may be coupled to multiple bitlines in a memory layer at the input side and coupled to the sense amplifier at the output side. The sense amplifier may also be coupled to one bitline in another memory layer. The multiplex ratio of the multiplexer may be the same as the ratio of conductor pitches of the two memory layers. The logic layer may include other components than sense amplifiers and wordline drivers. The components of the logic layer may be formed with transistors fabricated through a CMOS process.

Compared with currently available IC devices in which different memory layers have separate logic circuits, the cost for manufacturing the IC devices in the present disclosure is lower as different memory layers can share the same logic circuit. Also, the IC devices in the present disclosure can have better performance, such as less latency, better bandwidth, and higher density.

It should be noted that, in some settings, the term “nanoribbon” has been used to describe an elongated semiconductor structure that has a substantially rectangular transverse cross section (e.g., a cross section in a plane perpendicular to the longitudinal axis of the structure), while the term “nanowire” has been used to describe a similar structure but with a substantially circular or square transverse cross-sections. In the following, a single term “nanoribbon” is used to describe an elongated semiconductor structure independent of the shape of the transverse cross section. Thus, as used herein, the term “nanoribbon” is used to cover elongated semiconductor structures that have substantially rectangular transverse cross-sections (possibly with rounded corners), elongated semiconductor structures that have substantially square transverse cross-sections (possibly with rounded corners), elongated semiconductor structures that have substantially circular or elliptical/oval transverse cross-sections, as well as elongated semiconductor structures that have any polygonal transverse cross-sections. A longitudinal axis of a structure refers to a line (e.g., an imaginary line) that runs down the center of the structure in a direction perpendicular to a transverse cross section of the structure.

In the following, some descriptions may refer to a particular S source or drain (S/D) region or contact being either a source region/contact or a drain region/contact. However, unless specified otherwise, which region/contact of a transistor is considered to be a source region/contact and which region/contact is considered to be a drain region/contact is not important because, as is common in the field of FETs, designations of source and drain are often interchangeable. Therefore, descriptions of some illustrative embodiments of the source and drain regions/contacts provided herein are applicable to embodiments where the designation of source and drain regions/contacts may be reversed.

The systems, methods and devices of this disclosure each have several innovative aspects, no single one of which is solely responsible for the all of the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art. For example, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. As used herein, a “logic state” (or, alternatively, a “state” or a “bit” value) of a memory cell may refer to one of a finite number of states that the cell can have, e.g., logic states “1” and “0,” each state represented by a different voltage of the capacitor of the cell, while “READ” and “WRITE” memory access or operations refer to, respectively, determining/sensing a logic state of a memory cell and programming/setting a logic state of a memory cell. If used, the terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−20% of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−5-20% of a target value based on the context of a particular value as described herein or as known in the art. Also, the term “or” refers to an inclusive “or” and not to an exclusive “or.”

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the term “or” refers to an inclusive “or” and not to an exclusive “or.” The phrase “A and/or B” or the phase “A or B” means (A), (B), or (A and B). For the purposes of the present disclosure, the phrase “A, B, and/or C” or the phase “A, B, or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

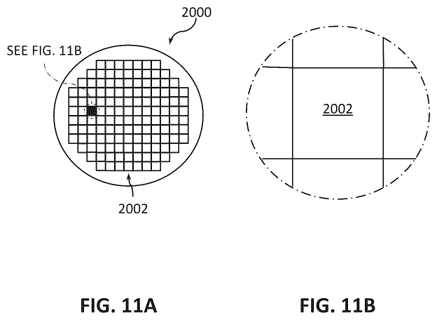

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense. For convenience, if a collection of drawings designated with different letters are present, e.g., FIGS. 11A-11B, such a collection may be referred to herein without the letters, e.g., as “FIG. 11.”

In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

Various IC devices with stacked memory devices as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

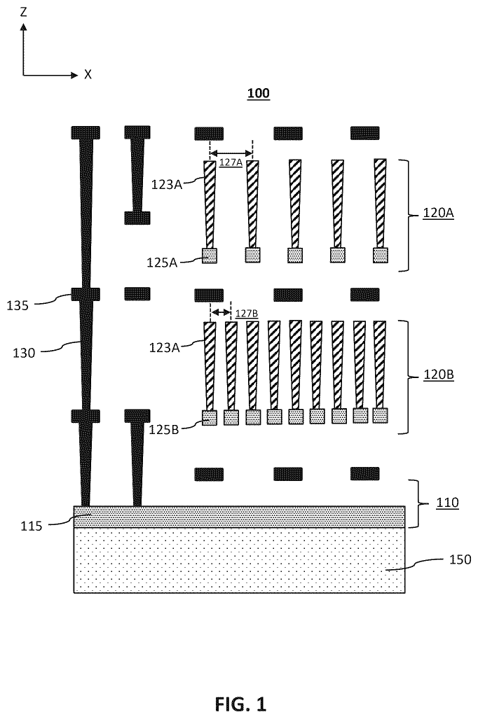

FIG. 1 illustrates an example IC device 100 including a heterogeneous memory stack with a shared logic circuit, according to some embodiments of the disclosure. The shared logic circuit is in a logic layer 110 of the heterogeneous memory stack. The heterogeneous memory stack further includes memory layers 120A and 120B (collectively referred to as “memory layers 120” or “memory layer 120”) over the logic layer 110, vias 130 (individually referred to as “via 130”), and conductive structures 135 (individually referred to as “conductive structure 135”). The IC device 100 also includes a device region 150. For the purpose of illustration and simplicity, not all components of the IC device 100 are shown in FIG. 1. In other embodiments, the IC device 100 may include different, fewer, or more components. For instance, the IC device 100 may include more than two memory layers over the logic layer 110.

The logic layer 110 controls the memory layers 120. The logic layer 110 may include one or more logic circuits that control operations of the memory layers 120. A logic circuit may be a peripheral circuit. A logic circuit may include transistors fabricated through a CMOS process. For instance, the transistors can be used to form wordline drivers, row decoders, sense amplifiers, column decoders, timers, multipliers, power delivery network, signal delivery network, or other types of devices or circuits in the logic layer 110.

A row decoder may select which rows of memory cells in memory arrays to be accessed based on memory addresses. In some embodiments, the row decoder may receive an input signal with information indicating a memory address. The row decoder may decode the memory address and select the row(s) corresponding to the memory address. The row decoder may further activate the row(s), e.g., by selecting and enabling the wordline of each selected row. After a row is selected and activated, the logic circuit can perform read or write operations on the memory cells in the row. The row decoder may include a digital circuit that can be used to decode memory addresses, select rows of memory cells, or activate wordlines. The digital circuit may include one or more logic gates.

A wordline driver drives signals down wordlines. In some embodiments, the wordline driver may receive signals from another component of the logic layer 110 (e.g., a row decoder) or from a circuit outside the IC device 100. The wordline driver may amplify the signals and apply the amplified signals to wordlines, e.g., wordlines selected by a row decoder. The wordline driver can generate the necessary voltage levels to activate wordlines. In some embodiments, the wordline driver may be coupled to one or more row decoders and one or more wordlines. The wordline driver may be implemented between a row decoder and a wordline. In other embodiments, the wordline driver may be included in a row decoder. In some embodiments, the wordline driver may include one or more inverters to drive wordlines.

A column decoder selects which column(s) of memory cells in memory arrays to be accessed based on memory addresses received from a logic circuit. The column decoder may decode a column address and activate the corresponding column of memory cells. The column decoder may include a digital circuit that can take the column address as input and generate one or more control signals that activate the corresponding column of memory cells. The digital circuit may include a combination of logic gates, such as AND gates and inverters, to decode the address and generate the necessary control signals. The number of inputs and outputs of the column decoder may depend on the size of the memory array. For example, in a memory system with 8 columns, the memory column decoder would have 3 address inputs (since 2\hat{ }3=8) and 8 output signals, each corresponding to a specific column. When a particular column address is provided, the column decoder may activate the corresponding output signal, enabling the memory cells in that column for read or write operations. The row decoder and column decoder can facilitate efficient and accurate access to specific rows of memory cells within the memory array and can support retrieval and storage of data in computer systems.

A sense amplifier may amplify and restore weak signals, e.g., to a more robust and usable level. In some embodiments, for reading data from the memory layers 120, the sense amplifier may detect and amplify the small voltage difference between the stored data states, typically representing binary values of 0 and 1. By amplifying this voltage difference, the sense amplifier can enable accurate and reliable data retrieval. In some embodiments (e.g., embodiments having high speed data transmission), the sense amplifier may amplify weak signals to avoid signal degradation and noise during signal propagation so that the signals can be more immune to noise, which can enable more accurate data recovery. The sense amplifier may be a latch-based sense amplifier, differential sense amplifier, dynamic sense amplifier, or other types of sense amplifiers. In some embodiments, the sense amplifier may be coupled to one or more column decoders and one or more bitlines. The sense amplifier may be implemented between a column decoder and a bitline. For instance, signals may be processed by the column decoder, then amplified by the sense amplifier before being provided to the bitline.

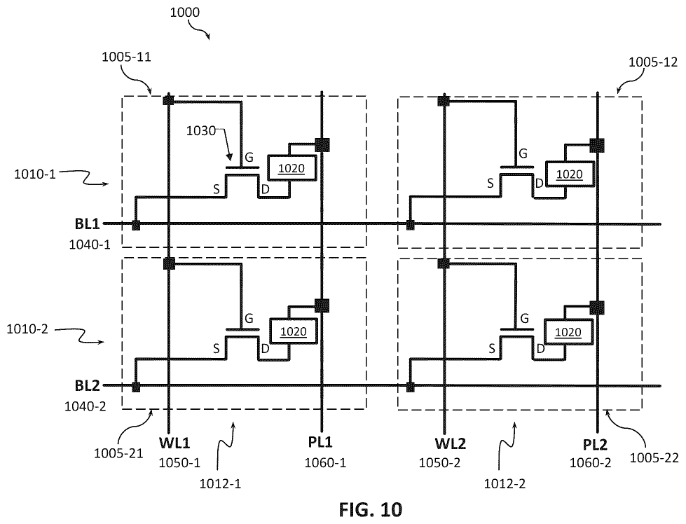

Each memory layer 120 may include one or more memory cells. In some embodiments, a memory layer 120 may be a memory die or memory wafer. Each memory layer 120 may include bitlines and wordlines. A bitline may be coupled to a column decoder and a sense amplifier, as described above. A wordline may be coupled to a row decoder and a wordline driver, as described above. In some embodiments, each memory layer 120 includes one or more memory arrays. A memory array may include memory cells arranged in rows and columns, one or more bitlines, and one or more wordlines. A row of memory cells may be coupled to a common wordline. A column of memory cells may be coupled to a common bitline. A memory cell may be activated or accessed (e.g., for data read or write operations) using the corresponding wordline and bitline. In some embodiments, the memory layers 120 may each include DRAM cells. A DRAM cell may include a memory element (e.g., a capacitor) and one or more access transistors. Example DRAM cells are shown in FIG. 10.

As shown in FIG. 1, the memory layer 120A includes conductive structures 123A (individually referred to as “conductive structure 123A”) and transistors 125A (individually referred to as “transistors 125A”). In some embodiments, each conductive structure 123A is in a capacitor. The capacitor and the transistor 125A coupled to the capacitor may constitute at least part of a memory cell in the memory layer 120A. The memory layer 120B includes conductive structures 123B (individually referred to as “conductive structure 123B”) and transistors 125B (individually referred to as “transistors 125B”). In some embodiments, each conductive structure 123B is in a capacitor. The capacitor and the transistor 125B coupled to the capacitor may constitute at least part of a memory cell in the memory layer 120B.

A conductive structure 123A or 123B may be formed of any suitable electrically conductive material, which may include an alloy or a stack of multiple electrically conductive materials. In some embodiments, such electrically conductive materials may include one or more metals or metal alloys, with metals such as ruthenium, palladium, platinum, cobalt, nickel, hafnium, zirconium, titanium, tantalum, and aluminum. In some embodiments, such electrically conductive materials may include one or more electrically conductive alloys oxides or carbides of one or more metals. The memory layer 120A may have a looser pitch than the memory layer 120B. The conductive structures 123A has a pitch 127A, which is a distance between the centers of two adjacent conductive structures 123A. The conductive structures 123B has a pitch 127B, which is a distance between the centers of two adjacent conductive structures 123B. In some embodiments, the pitch 127A is approximately 1.25 to approximately 4 times of the pitch 127B. In some embodiments, the pitch 127A or the pitch 127B may be in a range from approximately 35 nanometers to 300 nanometers.

Even though the pitch 127A and 127B are pitches of the conductive structures 123A and 123B in FIG. 1, the pitch 127A or 127B may be the pitch of other conductive structures in the IC device 100. For instance, the pitch 127A or 127B may be the pitch of transistor electrodes (e.g., source electrode, drain electrodes, or gate electrodes) or the pitch of control lines (e.g., bitlines, wordlines, etc.). Even though FIG. 1 shows two memory layers 120, the IC device 100 may include one or more other memory layers that have the same pitch as the memory layer 120A or 120B or one or more different pitches in other embodiments. Also, the memory layer 120A may be arranged between the memory layer 120B and the logic layer 110 in other embodiments.

In addition to the transistor 125A and 125B, the IC device 100 may also include transistors in the logic layer 110. The transistors in the logic layer 110 may be formed based on a device region 115. In some embodiments, a transistor (e.g., a transistor 125A, a transistor 125B, or a transistor in the logic layer 110) may be a field-effect transistor (FET), such as metal-oxide-semiconductor FET (MOSFET), tunnel FET (TFET), fin-based transistor (e.g., FinFET), nanoribbon-based transistor, nanowire-based transistor, gate-all-around (GAA) transistor, other types of FET, or some combination thereof. A transistor may include a semiconductor structure that provides the channel region, source region, and drain region of the transistor. The semiconductor structure may have a non-planar structure, such as a fin, nanoribbon, nanowire, and so on. A transistor may also include a gate that is over or wraps around the channel region. A transistor may also include a source electrode over the source region and a drain electrode over the drain region. The gate, sound electrode, or drain electrode may be electrically coupled to a bitline or wordline.

The transistors in the logic layer 110 may be transistors fabricated through a CMOS process. In some embodiments, the logic layer 110 includes pairs of P-type transistors (e.g., P-channel metal oxide semiconductor (PMOS) transistors) and N-type transistors (e.g., N-channel metal oxide semiconductor (NMOS) transistors). A P-type transistor may have P-type semiconductor regions (e.g., P-type source region and P-type drain region) with a N-type substrate (or an N-type body). An N-type transistor may have N-type semiconductor regions (e.g., N-type source region and N-type drain region) with a P-type substrate (or a P-type body). In some embodiments, the transistors 125A or 125B may be of the same type. In some embodiments, the architecture of transistors in the logic layer 110 may be different from that of a transistor 125A or 125B. In an example, the transistors in the logic layer 110 may have nanoribbon or nanowire semiconductor structures, while a transistor 125A or 125B may have a fin-shaped semiconductor structure. As another example, a transistor 125A or 125B may have a semiconductor region with a smaller cross-section than a transistor in the logic layer 110.

A source region or drain region may include a semiconductor material with dopants. An N-type source region or drain region may include a semiconductor material with N-type dopants. N-type dopants can introduce additional electrons into the crystal lattice of a semiconductor material and are also known as “donor” impurities. A P-type source region or drain region may include a semiconductor material with P-type dopants. P-type dopants can introduce additional holes into the crystal lattice and are also known as “acceptor” impurities. Example N-type dopants include Te, S, As, tin (Sn), Si, Ga, Se, S, In, Al, Cd, chlorine (CI), iodine (I), fluorine (F), and so on. Example P-type dopants include beryllium (Be), Zn, magnesium (Mg), Sn, P, Te, lithium (Li), sodium (Na), Ga, Cd, and so on.

In an N-type transistor, the source and drain regions may be doped with N-type dopants with dopant concentrations of at least 10¹⁷ dopants per cubic centimeter (cm⁻³), or more, e.g., with dopant concentrations of at least 10¹⁸ cm⁻3 or with dopant concentrations of at least 10²⁰ cm⁻³ to create regions with an excess of electrons that can serve as the majority charge carriers during operation of the N-type transistor. In a P-type transistor, the source and drain regions may be doped with P-type dopants with dopant concentrations of at least 10¹⁷ cm⁻³, or more, e.g., with dopant concentrations of at least 10¹⁸ cm 3 or with dopant concentrations of at least 10²⁰ cm⁻³ to create regions with an excess of holes (or deficiencies of electrons) that can serve as the majority charge carriers during operation of the P-type transistor. In some embodiments, a source region or drain region may be highly doped, e.g., with dopant concentrations of about 1·10²¹ cm⁻³, in order to advantageously form Ohmic contacts with the respective S/D contacts (also sometimes interchangeably referred to as “S/D electrodes”), although these regions may also have lower dopant concentrations and may form Schottky contacts in some implementations. Irrespective of the exact doping levels, the source region and the drain region of a transistor may be the regions having dopant concentration higher than in other regions, e.g., higher than a dopant concentration in the channel region, and, therefore, may be referred to as “highly doped” (HD) regions.

A semiconductor material of a source region or drain region may be a Group IV material, a compound of Group IV materials, a Group III/V material, a compound of Group III/V materials, a Group II/VI material, a compound of Group II/VI materials, or other semiconductor materials. Example Group II materials include zinc (Zn), cadmium (Cd), and so on. Example Group III materials include aluminum (AI), boron (B), indium (In), gallium (Ga), and so on. Example Group IV materials include Si, Ge, carbon (C), etc. Example Group V materials include nitrogen (N), phosphorus (P), arsenic (As), antimony (Sb), and so on. Example Group VI materials include sulfur(S), selenium (Se), tellurium (Te), oxygen (O), and so on. A compound of Group IV materials can be a binary compound, such as SiC, SiGe, and so on. A compound of Group III/V materials can be a binary, tertiary, or quaternary compound, such as GaN, InN, and so on. A compound of Group II/VI materials can be a binary, tertiary, or quaternary compounds, such as CdSe, CdS, CdTe, ZnO, ZnSe, ZnS, ZnTe, CdZnTe, CZT, HgCdTe, HgZnTe, and so on.

In some embodiments, the dopants in the source region and the drain region of a transistor are the same type. In other embodiments, the dopants of the source region and the drain region may be different (e.g., opposite) types. In an example, the source region has N-type dopants, and the drain region has P-type dopants. In another example, the source region has P-type dopants, and the drain region has N-type dopants. In some embodiments, the source region or drain region of a transistor have the same semiconductor material, which may be the same as the channel material of the channel region.

A channel region of a transistor may include one or more channel materials. A channel material may be composed of semiconductor material systems including, for example, N-type or P-type materials systems. In some embodiments, the channel material may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the channel material may include a combination of semiconductor materials where one semiconductor material may be used for a channel portion of a transistor and another material, sometimes referred to as a “blocking material,” may be used between the channel portion and the support structure over which the transistor is provided. In some embodiments, the channel material may include a monocrystalline semiconductor, such as silicon (Si) or germanium (Ge). In some embodiments, the channel material may include a compound semiconductor with a first sub-lattice of at least one element from Group III of the periodic table (e.g., Al, Ga, In), and a second sub-lattice of at least one element of group V of the periodic table (e.g., P, As, Sb).

For some example N-type transistor embodiments (i.e., for the embodiments where the transistors implemented in the memory layers 120 are NMOS transistors), the channel portions of the channel material may advantageously include a III-V material having a high electron mobility, such as, but not limited to InGaAs, InP, InSb, and InAs. For some such embodiments, the channel portions of the channel material may be a ternary III-V alloy, such as InGaAs, GaAsSb, InAsP, or InPSb. For some InₓGa₁₋ₓAs fin embodiments, In content (x) may be between 0.6 and 0.9, and may advantageously be at least 0.7 (e.g., In_{0.7}Ga_{0.3}As). In some embodiments with highest mobility, the channel portions of the channel material may be an intrinsic III-V material, i.e., a III-V semiconductor material not intentionally doped with any electrically active impurity. In alternate embodiments, a nominal impurity dopant level may be present within the channel portions of the channel material, for example to further fine-tune a threshold voltage Vt, or to provide HALO pocket implants, etc. Even for impurity-doped embodiments however, impurity dopant level within the channel portions of the channel material may be relatively low, for example below 10¹⁵ dopant atoms per cubic centimeter (cm⁻³), and advantageously below 10¹³ cm⁻³.

For some example P-type transistor embodiments (i.e., for the embodiments where the transistors implemented in the memory layers 120 are PMOS transistors), the channel portions of the channel material may advantageously be a Group IV material having a high hole mobility, such as, but not limited to Ge or a Ge-rich SiGe alloy. For some example embodiments, the channel portions of the channel material may have a Ge content between 0.6 and 0.9, and advantageously may be at least 0.7. In some embodiments with highest mobility, the channel portions of the channel material may be intrinsic III-V (or IV for P-type devices) material and not intentionally doped with any electrically active impurity. In alternate embodiments, one or more nominal impurity dopant levels may be present within the channel material, for example to further set a threshold voltage (Vt), or to provide HALO pocket implants, etc. Even for impurity-doped embodiments however, impurity dopant level within the channel portions of the channel material is In some embodiments, for a thin-film transistor (TFT), the channel material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, molybdenum disulfide, N- or P-type amorphous or polycrystalline silicon, monocrystalline silicon, germanium, indium arsenide, indium gallium arsenide, indium selenide, indium antimonide, zinc antimonide, antimony selenide, silicon germanium, gallium nitride, aluminum gallium nitride, indium phosphite, black phosphorus, zinc sulfide, indium sulfide, gallium sulfide, each of which may possibly be doped with one or more of gallium, indium, aluminum, fluorine, boron, phosphorus, arsenic, nitrogen, tantalum, tungsten, and magnesium, etc. In some embodiments, a thin-film channel material may be deposited at relatively low temperatures, which allows depositing the channel material within the thermal budgets imposed on back-end fabrication to avoid damaging other components, e.g., front end components such as logic devices.

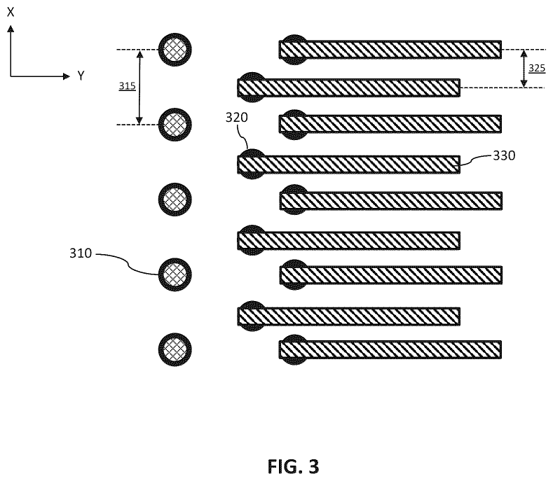

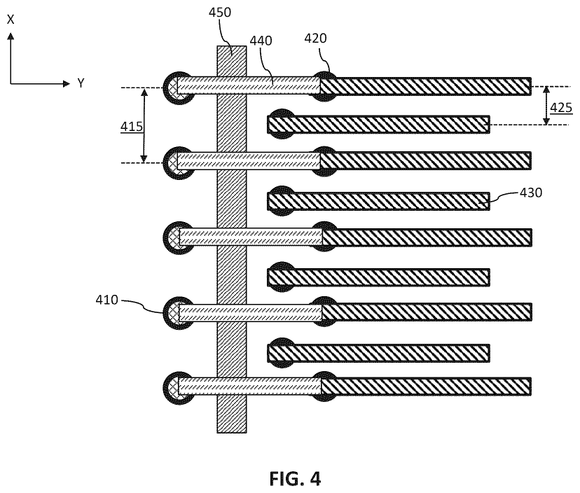

The vias 130 and conductive structures 135 facilitate electrical connections in the IC device 100, such as cross-layer connections. In some embodiments, a via 130 may have a longitudinal axis that is perpendicular to a plane where the transistors 125A are placed, a plane where the transistors 125B are placed, a plane of the device region 115, or a plane of the device region 150. The conductive structures 135 may be parallel to one or more of these planes. In some embodiments, a conductive structure 135 may be an interconnect, such as a metal line in a metal layer. As shown in FIG. 1, the vias 130 and some conductive structures 135 couples the logic layer 110 to both of the memory layers 120. The cross-layer electrical connection can allow the logic circuits in the logic layer 110 to send or receive signals from the memory layers 120. Also, the logic layer 110 may deliver power to the memory layers 120. Certain aspects of cross-layer connection are described below in conjunction with FIGS. 3 and 4.

The device region 150 may be any suitable support structure, such as a substrate, a die, a wafer, or a chip, based on which at least part of the logic layer 110 may be formed. In some embodiments, the device region 150 may be a semiconductor substrate composed of semiconductor material systems including, for example, N-type or P-type materials systems. In some embodiments, the semiconductor substrate may be a crystalline substrate formed using a bulk silicon or a silicon-on-insulator (SOI) substructure. In other embodiments, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of Group III-V, Group II-VI, or Group IV materials. In some embodiments, the substrate may be non-crystalline. In some embodiments, the device region 150 may be a printed circuit board (PCB) substrate. One or more transistors, such as transistors in the logic layer 110 may be built on the device region 150. An example of the device region 150 may be the wafer 2000 in FIG. 11A. Another example of the device region 150 may be the die 2002 in FIG. 11B or a device region that includes the die 2002 in FIG. 11B.

Although a few examples of materials from which the device region 150 may be formed are described here, any material that may serve as a foundation upon which an IC may be built falls within the spirit and scope of the present disclosure. In various embodiments, the device region 150 may include any such support structure, possibly with some layers and/or devices already formed thereon, not specifically shown in the present figures. As used herein, the term “support” does not necessarily mean that it provides mechanical support for the IC devices/structures (e.g., transistors, capacitors, interconnects, and so on) built thereon. For example, some other structure (e.g., a carrier substrate or a package substrate) may provide such mechanical support and the device region 150 may provide material “support” in that, e.g., the IC devices/structures described herein are build based on the semiconductor materials of the device region 150. However, in some embodiments, the device region 150 may be a support structure that provides mechanical support.

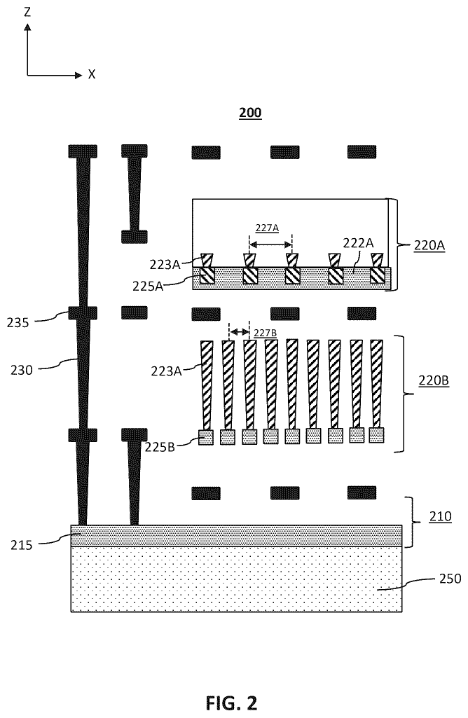

FIG. 2 illustrates another example IC device 200 including a heterogeneous memory stack with a shared logic circuit, according to some embodiments of the disclosure. The shared logic circuit is in a logic layer 210 of the heterogeneous memory stack. The heterogeneous memory stack further includes memory layers 220A and 220B (collectively referred to as “memory layers 220” or “memory layer 220”) over the logic layer 210, vias 230 (individually referred to as “via 230”) and conductive structures 235 (individually referred to as “conductive structure 235”). The IC device 200 also includes a device region 250. For the purpose of illustration and simplicity, not all components of the IC device 200 are shown in FIG. 2. In other embodiments, the IC device 200 may include different, fewer, or more components. For instance, the IC device 200 may include more than two memory layers over the logic layer 210.

The logic layer 210 controls the memory layers 220. The logic layer 210 may include one or more logic circuits that control operations of the memory layers 220. A logic circuit may be a peripheral circuit. A logic circuit may include transistors fabricated through a CMOS process. For instance, the transistors can be used to form wordline drivers, row decoders, sense amplifiers, column decoders, timers, multipliers, power delivery network, signal delivery network, or other types of devices or circuits in the logic layer 210.

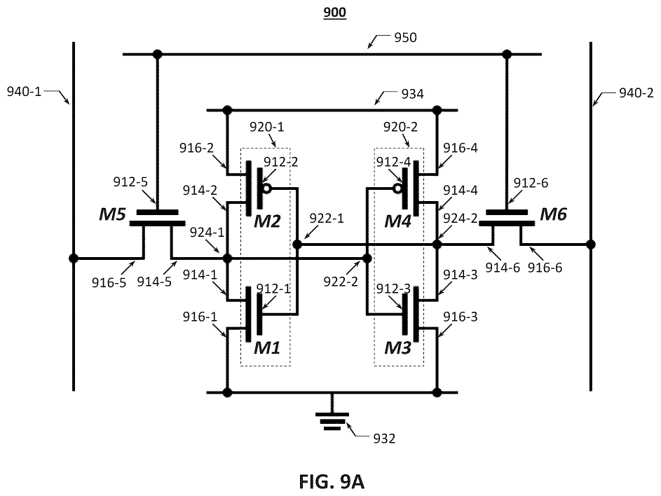

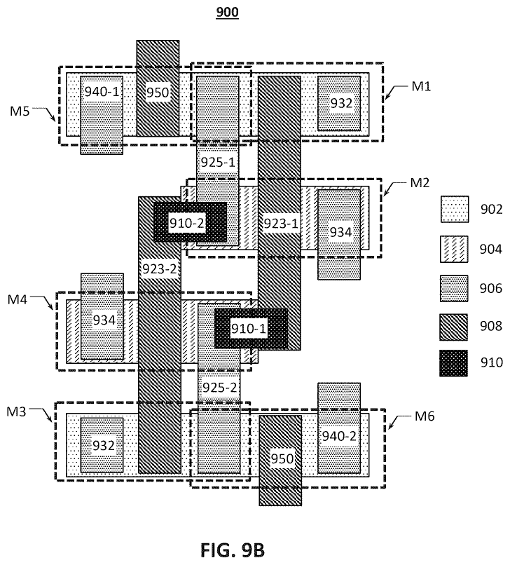

Each memory layer 220 may include one or more memory cells. In some embodiments, a memory layer 220 may be a memory die or memory wafer. Each memory layer 220 may include bitlines and wordlines. A bitline may be coupled to a column decoder and a sense amplifier, as described above. A wordline may be coupled to a row decoder and a wordline driver, as described above. In some embodiments, each memory layer 220 includes one or more memory arrays. A memory array may include memory cells arranged in rows and columns, one or more bitlines, and one or more wordlines. A row of memory cells may be coupled to a common wordline. A column of memory cells may be coupled to a common bitline. A memory cell may be activated or accessed (e.g., for data read or write operations) using the corresponding wordline and bitline. In some embodiments, the memory layer 220A may include SRAM cells. A SRAM cell may include transistors coupled with bitlines and wordlines. An example SRAM cell is shown in FIGS. 9A and 9B. In some embodiments, the memory layer 220B may include DRAM cells. A DRAM cell may include a memory element (e.g., a capacitor) and one or more access transistors. Example DRAM cells are shown in FIG. 10.

As shown in FIG. 2, the memory layer 220A includes conductive structures 223A (individually referred to as “conductive structure 223A”) and a device region 222A with active regions 225A (individually referred to as “active region 225A”). The device region 222A may be a substrate based on which transistors may be formed. The device region 222A may be the same or similar as the device region 150 in FIG. 1. In some embodiments, an active region 225A may include one or more semiconductor structures, which may provide semiconductor regions of transistors. In some embodiments, the conductive structures 223A may be electrodes of the transistors, such as source electrodes, drain electrodes, or gate electrodes. Even though not shown in FIG. 2, the memory layer 220A may include additional conductive structures over the conductive structures 223A, which may be interconnects that can be used as lines, such as bitlines or wordlines. The memory layer 220B includes conductive structures 223B (individually referred to as “conductive structure 223B”) and transistors 225B (individually referred to as “transistors 225B”). In some embodiments, each conductive structure 223B is in a capacitor. The capacitor and the transistor 225B coupled to the capacitor may constitute at least part of a memory cell in the memory layer 220B.

A conductive structure 223A or 223B may be formed of any suitable electrically conductive material, such as the electrically conductive materials described above. The memory layer 220A may have a looser pitch than the memory layer 220B. The conductive structures 223A has a pitch 227A, which is a distance between the centers of two adjacent conductive structures 223A. The conductive structures 223B has a pitch 227B, which is a distance between the centers of two adjacent conductive structures 223B. The pitch 227A is larger than the pitch 227B. In some embodiments, the pitch 127A is approximately 1.25 to approximately 4 times of the pitch 127B. In some embodiments, the pitch 127A or the pitch 127B may be in a range from approximately 35 nanometers to 300 nanometers. For the purpose of illustration, FIG. 2 shows two memory layers 120. In other embodiments, the IC device 200 may include one or more other memory layers that have the same pitch as the memory layer 220A or 220B or one or more different pitches. Even though the memory layer 220B is between the memory layer 220A and the logic layer 210 in FIG. 2, the memory layer 220A may be arranged between the memory layer 220B and the logic layer 210 in other embodiments.

In addition to the transistors formed based on the device region 222A and the transistors 225B, the IC device 200 may also include transistors in the logic layer 210, which may be formed based on a device region 215. The device region 215 may be the same or similar as the device region 115 in FIG. 1. In some embodiments, a transistor (e.g., a transistor in the memory layer 220A, the memory layer 220B, or the logic layer 210) may be a FET, such as MOSFET, TFET, FinFET, nanoribbon-based transistor, nanowire-based transistor, GAA transistor, other types of FET, or some combination thereof. A transistor may include a semiconductor structure that provides the channel region, source region, and drain region of the transistor. The semiconductor structure may have a non-planar structure, such as a fin, nanoribbon, nanowire, and so on. A transistor may also include a gate that is over or wraps around the channel region. A transistor may also include a source electrode over the source region and a drain electrode over the drain region. The gate, sound electrode, or drain electrode may be electrically coupled to a bitline or wordline.

The transistors in the logic layer 210 may be transistors fabricated through a CMOS process. In some embodiments, the logic layer 210 includes pairs of P-type transistors (e.g., PMOS transistors) and N-type transistors (e.g., NMOS transistors). In some embodiments, the transistor in a memory layer 220 may be of the same type. In some embodiments, the architecture of transistors in the logic layer 210 may be different from that of transistors in the memory layer 220A or 220B. In an example, the transistors in the logic layer 210 may have nanoribbon or nanowire semiconductor structures, while transistors in the memory layer 220A or 220B may have fin semiconductor structures. As another example, transistors in the memory layer 220A or 220B may have semiconductor regions with smaller cross-sections than transistors in the logic layer 210.

The vias 230 and conductive structures 235 facilitate electrical connections in the IC device 200, including cross-layer connections. In some embodiments, a via 230 may have a longitudinal axis that is perpendicular to a plane where the device region 222A is placed, a plane where the transistors 225B are placed, a plane of the device region 215, or a plane of the device region 250. The conductive structures 235 may be parallel to one or more of these planes. In some embodiments, a conductive structure 235 may be an interconnect, such as a metal line in a metal layer. As shown in FIG. 2, the vias 230 and some conductive structures 235 couples the logic layer 210 to both of the memory layers 220. The cross-layer electrical connection can allow the logic circuits in the logic layer 210 to send or receive signals from the memory layers 220. Also, the logic layer 210 may deliver power to the memory layers 220. Certain aspects of cross-layer connection are described below in conjunction with FIGS. 3 and 4. The device region 250 may be the same or similar as the device region 150.

FIG. 3 illustrates electrical connections in a heterogeneous memory stack, according to some embodiments of the disclosure. The heterogeneous memory stack may include a logic circuit shared by multiple memory layers that have different pitches. The heterogeneous memory stack in FIG. 3 may be an example of the heterogeneous memory stack in FIG. 1 or the heterogeneous memory stack in FIG. 2. FIG. 3 shows five vias 310 (individually referred to as “via 310”) that couple the logic circuit (e.g., the logic layer 110 or 210) to a first memory layer. FIG. 3 also shows nine vias 320 (individually referred to as “via 320”) and nine conductive structures 330 (individually referred to as “conductive structure 330”) that couple the logic circuit to a second memory layer. The conductive structures 330 may be transistor electrodes, control lines, interconnects, or conductors of capacitors. In other embodiments, the heterogeneous memory stack may include a different number of vias 310 or 320 or a different number of conductive structures 330 for the electrical connections.

The pitch of the first memory layer may be a distance 315 between the centers of two adjacent vias 310. The pitch of the second memory layer may be a distance 325 between the centers of two adjacent vias 320 or between the centers of two adjacent conductive structures 330. As shown in FIG. 3, the distance 315 is greater than the distance 325. The first memory layer has a looser pitch than the second memory layer. Examples of the first memory layer include the memory layer 120A in FIG. 1 and the memory layer 220A in FIG. 2. Examples of the second memory layer include the memory layer 120B in FIG. 1 and the memory layer 220B in FIG. 2.

FIG. 4 illustrates cross-layer connections in a heterogeneous memory stack, according to some embodiments of the disclosure. The heterogeneous memory stack may include a logic circuit shared by multiple memory layers that have different pitches. The heterogeneous memory stack in FIG. 4 may be an example of the heterogeneous memory stack in FIG. 1 or the heterogeneous memory stack in FIG. 2. FIG. 4 shows five vias 410 (individually referred to as “via 410”) that couple the logic circuit (e.g., the logic layer 110 or 210) to a first memory layer. FIG. 4 also shows nine vias 420 (individually referred to as “via 420”) and nine conductive structures 430 (individually referred to as “conductive structure 430”) that couple the logic circuit to a second memory layer. The conductive structures 430 may be transistor electrodes, control lines, interconnects, or conductors of capacitors.

The pitch of the first memory layer may be a distance 415 between the centers of two adjacent vias 410. The pitch of the second memory layer may be a distance 425 between the centers of two adjacent vias 420 or between the centers of two adjacent conductive structures 430. As shown in FIG. 4, the distance 415 is greater than the distance 425. The first memory layer has a looser pitch than the second memory layer. Examples of the first memory layer include the memory layer 120A in FIG. 1 and the memory layer 220A in FIG. 2. Examples of the second memory layer include the memory layer 120B in FIG. 1 and the memory layer 220B in FIG. 2.

The first memory layer is coupled to the second memory layer through five conductive structures 440, individually referred to as “conductive structure 440.” Each conductive structure 440 has an end connected to a via 410 and another end connected to the via 420 or a conductive structure 430. In some embodiments, a bitline in the first memory layer may be coupled to a bitline in the second memory layer through the conductive structure 440. The two bitlines in different memory layers may be coupled to the same sense amplifier in the logic circuit. In other embodiments, a wordline in the first memory layer may be coupled to a wordline in the second memory layer through the conductive structure 440. The two wordline in different memory layers may be coupled to the same wordline driver in the logic circuit.

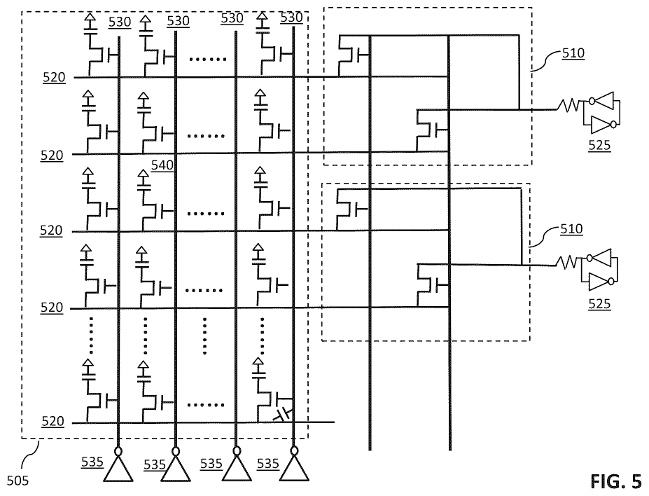

As the second memory layer has a tighter pitch, there are more vias 420 than vias 410. In some embodiments, multiple vias 420 may be coupled to the same via 410. For instance, the pitch of the first memory layer in FIG. 4 is double the pitch of the second memory layer. Two vias 420 may be coupled to one via 410. Such connection may be facilitated by a multiplexer having a multiplex ratio of 2:1. Certain aspects of multiplexing for cross-layer connection are provided below in conjunction with FIG. 5.

The heterogeneous memory stack also includes a conductive structure 450. The conductive structure 450 may be perpendicular to the conductive structures 430. The conductive structure 450 may provide gate electrodes of various transistors in the heterogeneous memory stack. For instance, the conductive structure 450 may function as gate electrodes of transistors in multiplexers that facilitate the cross-layer connection. The multiplexers may include CMOS transistors (e.g., PMOS-NMOS transistor pair) or N-type transistors. In other embodiments, the heterogeneous memory stack may include a different number of vias 410 or 420 or a different number of conductive structures 440 for electrical connections between the logic circuit, the first memory layer, and the second memory layer.

FIG. 5 is an electric circuit diagram of a heterogeneous memory stack 500 with multiplexers 510 for cross-layer connection, according to some embodiments of the disclosure. For the purpose of illustration, FIG. 5 does not show all the components of the heterogeneous memory stack 500. The multiplexers 510 may be individually referred to as “multiplexer 510.” As shown in FIG. 5, the heterogeneous memory stack 500 also includes a memory array 505, sense amplifiers 525, and wordline drivers 535. The memory array 505 may be in a memory layer of the heterogeneous memory stack 500. The heterogeneous memory stack 500 may include one or more other memory layers (not shown in FIG. 5) that have a looser pitch than the memory layer including the memory array 505. All the memory layers of the heterogeneous memory stack may share the same logic circuit. The shared logic circuit may include the sense amplifiers 525 (individually referred to as “sense amplifier 525”) and the wordline drivers 535 (individually referred to as “wordline driver 535”). The heterogeneous memory stack 500 may be an example of the heterogeneous memory stack in FIG. 1, FIG. 2, FIG. 3, or FIG. 4.

The memory array 505 includes bitlines 520 (individually referred to as “bitline 520”) and wordlines 530 (individually referred to as “wordline 530”), and memory cells 540 (individually referred to as “memory cell 540”). Each memory cell includes a capacitor and a transistor. The gate electrode of the transistor may be coupled to a wordline 530. A source electrode of the transistor may be coupled to a bitline 520. A drain electrode of the transistor may be coupled to the capacitor.

Each sense amplifier 525 is coupled to two bitlines 520 through a multiplexer 510. The multiplexer 510 has an input end that receives two bitlines 520 and an output end that is connected to the sense amplifier 525. The multiplex ratio of the multiplexer 510 is 2:1. Even though not shown in FIG. 5, the sense amplifier 525 may be coupled to a bitline in another memory layer of the heterogeneous memory stack 500 so that bitlines in different memory layers may be controlled by the same sense amplifier 525. The other memory layer may have a looser pitch than the memory layer including the memory array 505. For instance, the pitch of the other memory layer may be double the pitch of the memory layer including the memory array 505. In other embodiments, the multiplex ratio may be different, and the ratio of the pitches of memory layers may also be different.

In some embodiments, the wordlines 530 in FIG. 5 are not electrically coupled. The wordlines 530 may be separated from each other by one or more insulators. Even though multiplexers are used for coupling bitlines in the embodiments of FIG. 5, multiplexers may also be used for coupling wordlines in other embodiments. For instance, the input side of a multiplexer may be coupled to two wordlines and the output side of the multiplexer may be coupled to one wordline driver. In such embodiment, the bitlines may be separated from each other by one or more insulators.

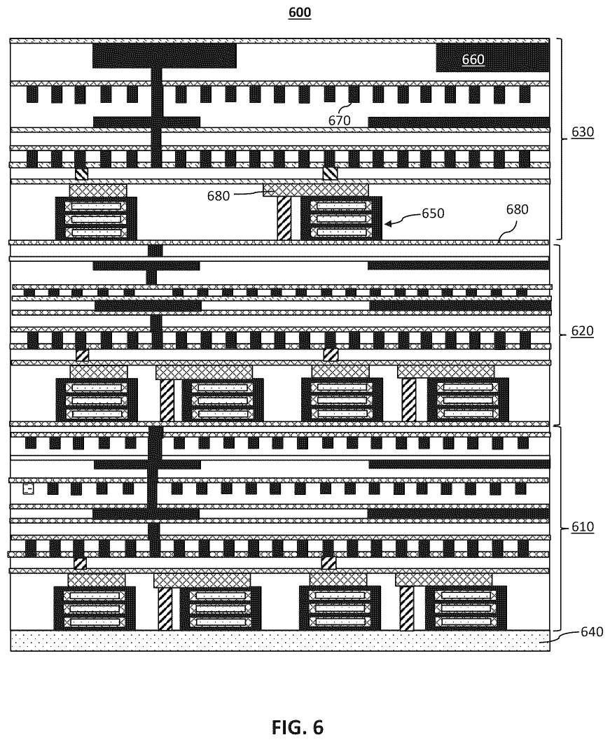

FIG. 6 is a cross-sectional view of a heterogeneous memory stack 600, according to some embodiments of the disclosure. The heterogeneous memory stack 600 may be an example of the heterogeneous memory stack in FIG. 1, FIG. 2, FIG. 3, or FIG. 4. The heterogeneous memory stack 600 includes a logic layer 610, a memory layer 620, and a memory layer 630, and a device region 640. The logic layer 610 may be shared by the memory layers 620 and 630. For example, sense amplifiers in the logic layer 610 may be coupled to bitlines in both of the memory layers 620 and 630. As another example, wordline drivers in the logic layer 610 may be coupled to wordlines in both of the memory layers 620 and 630. In some embodiments, the logic layer 610 may send or receive signals from the memory layers 620 and 630. The logic layer 610 may also deliver power to the memory layers 620 and 630. The device region 640 may be a substrate based on which the logic layer 610 is formed. The device region 640 may be an example of the device region 150 in FIG. 1 or the device region 250 in FIG. 2.

Each of the logic layer 610, memory layer 620, and memory layer 630 includes transistors 650 (individually referred to as “transistor 650”), interconnects 660 (individually referred to as “interconnect 660”), and vias 670 (individually referred to as “via 670”). For the purpose of illustration and simplicity, the transistors 650 are shown as GAA transistors. In other embodiments, a transistor 650 can be of a different type. Also, transistors 650 in different layers of the heterogeneous memory stack 600 may be different, e.g., as described above. The memory layer 620 has a looser pitch than the memory layer 630. The pitch may be the distance between the same type of electrodes of two adjacent transistors in the corresponding memory layer. The interconnects 660 and vias 670 may facilitate electrical connections in the heterogeneous memory stack 600. A component in the logic layer 610 may be coupled to a component in the memory layer 620 or a component in the memory layer 630. In some embodiments, a component in the memory layer 620 may be coupled to a component in the memory layer 630.

Various sections of the heterogeneous memory stack 600 are separated by insulator structures 680, which are individually referred to as “insulator structure 680.” An insulator structure 680 may include one or more electrical insulators, such as dielectric materials, hysteretic materials, and so on. Examples of dielectric materials include oxide (e.g., silicon-based oxides, metal oxides, etc.), nitride, carbide, and so on. Examples of hysteretic materials include ferroelectric materials, antiferroelectric materials, etc.

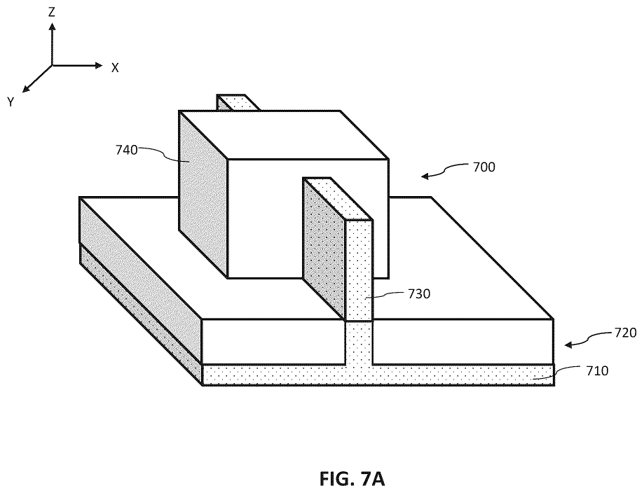

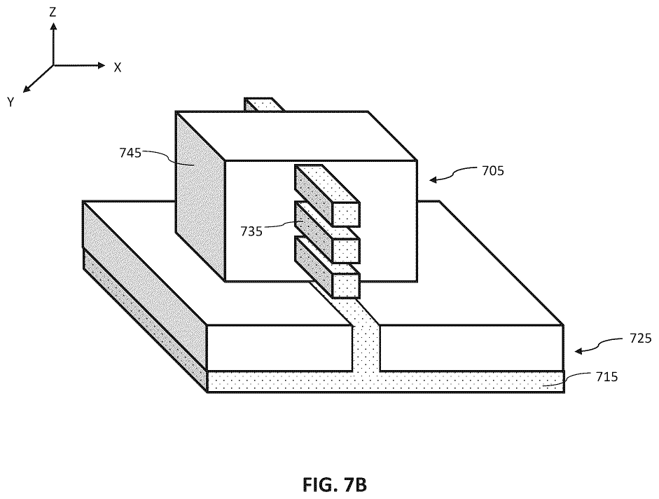

FIG. 7A shows a transistor 700 with a fin, according to some embodiments of the disclosure. The transistor 700 may be an embodiment of a transistor in a logic layer (e.g., the logic layer 110 and the logic layer 210) or in a memory layer (e.g., the memory layers 120 and the memory layers 220). The transistor 700 is over a support structure 710 and a dielectric layer 720. The transistor 700 includes a semiconductor structure 730 and a gate 740. In other embodiments, the transistor 700 may include fewer, more, or different components. For instance, the transistor 700 may include multiple semiconductor structures 730.

The support structure 710 may be any suitable structure, such as a substrate, a die, a wafer, or a chip, based on which transistors can be built. The dielectric layer 720 is over various portions of the support structure 710 along the Z axis. The dielectric layer 720 includes one or more dielectric materials, such as oxide or other low-k dielectric materials. Example oxide in the dielectric layer may include silicon oxide (SiO), silicon oxycarbide (SiOC), silicon oxycarbonitride (SiOCN), and so on. The support structure 710 may be an example of the device region 150, 222A, 250, or 640.

The semiconductor structures 730 are over the support structure 710. In the embodiments of FIG. 1, the semiconductor structures 730 have the shape of a fin with a longitudinal axis parallel to the Y axis and a transverse cross section parallel to the X-Z plane. A dimension of a semiconductor structure 730 along the Y axis may be greater than a dimension of the semiconductor structure 730 in another direction. The semiconductor structure 730 may provide the source region, channel region, and drain region of the transistor 700. A channel region of a transistor may include a channel material, such as channel materials described above. The source region and drain region in a transistor are connected to the channel region. The source region and drain region may each include a semiconductor material with dopants. In some embodiments, the source region and drain region have the same semiconductor material, which may be the same as the channel material of the channel region.

The dimensions of the semiconductor structures 730 may be different for different applications of the transistor 700. For example, compared with embodiments where the transistor 700 is used in a memory die, the cross section of each semiconductor structure 730 in the X-Z plane may be larger when the transistor 700 is used in a logic die. The width of each semiconductor structure 730 along the X axis may also be larger when the transistor 700 is used in a logic die.

The gate 740 is over the dielectric layer 720. In FIG. 7A, the gate 740 wraps around the semiconductor structures 730. The gate 740 and the semiconductor structures 730 may form GAA transistors. The gate 740 may include a gate electrode including one or more conductive materials, such as metal, polycrystalline silicon, other types of conductive materials, or some combination thereof. In some embodiments, the choice of the conductive materials in the gate 740 may depend on whether the transistor is a P-type transistor or an N-type transistor. For a P-type transistor, gate electrode materials that may be used in different portions of the gate electrode may include, but are not limited to, Ru, palladium, platinum, Co, nickel, and conductive metal oxides (e.g., ruthenium oxide). For an N-type transistor, gate electrode materials that may be used in different portions of the gate electrode, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide).

In some embodiments, the gate 740 may include a stack of a plurality of gate electrode materials, where zero or more materials of the stack are work function materials and at least one material of the stack is a fill metal layer. Further materials/layers may be included next to the gate electrode for other purposes, such as to act as a diffusion barrier layer or/and an adhesion layer. The gate 740 may also include a gate insulator, part of which may be between the gate electrode and each semiconductor structure 730. The gate 740 may be electrically coupled to a power plane, ground plane, or signal plane for facilitating power supply or signal transmission for the transistor 700.

FIG. 7B shows a transistor 705 with nanoribbons, according to some embodiments of the disclosure. The transistor 705 may be an embodiment of a transistor in a logic layer (e.g., the logic layer 110 and the logic layer 210) or in a memory layer (e.g., the memory layers 120 and the memory layers 220). The transistor 705 is over a support structure 715 and a dielectric layer 725. The transistor 705 includes a plurality of semiconductor structures 735 (individually referred to as “semiconductor structure 735”), which are stacked over each other along the Z axis, and a gate 745. In other embodiments, the transistor 705 may include fewer, more, or different components. For instance, the transistor 705 may include a different number of semiconductor structures. Semiconductor structures may be arranged differently in the transistor 705. For instance, two or more semiconductor structures may be stacked over each other along the X axis.

The support structure 715 may be any suitable structure, such as a substrate, a die, a wafer, or a chip, based on which transistors can be built. The dielectric layer 725 is over various portions of the support structure 715 along the Z axis. The dielectric layer 725 includes one or more dielectric materials, such as oxide or other low-k dielectric materials. Example oxide in the dielectric layer may include silicon oxide (SiO), silicon oxycarbide (SiOC), silicon oxycarbonitride (SiOCN), and so on. The support structure 715 may be an example of the device region 150, 222A, 250, or 640.

The semiconductor structures 735 are over the support structure 715. In the embodiments of FIG. 1, the semiconductor structures 735 have a nanoribbon shape with a longitudinal axis substantially parallel to the Y axis and a transverse cross section substantially parallel to the X-Z plane. A dimension of a semiconductor structure 735 along the Y axis may be greater than a dimension of the semiconductor structure 735 in another direction. The semiconductor structures 735 are arranged parallel to each other and are stacked in a direction along the Z axis. In other embodiments, a semiconductor structure 735 may have a different shape, e.g., fin, other non-planar shapes, or a planar shape.

A semiconductor structure 735 may provide the source region, channel region, and drain region of at least one transistor. A channel region of a transistor may include a channel material, such as channel materials described above. The source region and drain region in a transistor are connected to the channel region. The source region and drain region may each include a semiconductor material with dopants. In some embodiments, the source region and drain region have the same semiconductor material, which may be the same as the channel material of the channel region.

The dimensions of the semiconductor structures 735 may be different for different applications of the transistor 705. For example, compared with embodiments where the transistor 705 is used in a memory die, the cross section of each semiconductor structure 735 in the X-Z plane may be larger when the transistor 705 is used in a logic die. The width of each semiconductor structure 735 along the X axis may also be larger when the transistor 705 is used in a logic die. In some embodiments, the transistor 705 may be used in either a logic layer or a memory layer. A nanoribbon transistor in a logic layer may include more nanoribbons (e.g., approximately one to three times more) than a nanoribbon transistor in a memory layer. In some embodiments, the transistor 705 may be a transistor in a logic layer, and a transistor in a memory layer may be a FinFET.

The gate 745 is over the dielectric layer 725. In FIG. 7B, the gate 745 wraps around the semiconductor structures 735. The gate 745 and the semiconductor structures 735 may form GAA transistors. The gate 745 may include a gate electrode including one or more conductive materials, such as metal, polycrystalline silicon, other types of conductive materials, or some combination thereof. In some embodiments, the choice of the conductive materials in the gate 745 may depend on whether the transistor is a P-type transistor or an N-type transistor. For a P-type transistor, gate electrode materials that may be used in different portions of the gate electrode may include, but are not limited to, Ru, palladium, platinum, Co, nickel, and conductive metal oxides (e.g., ruthenium oxide). For an N-type transistor, gate electrode materials that may be used in different portions of the gate electrode, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide).

In some embodiments, the gate 745 may include a stack of a plurality of gate electrode materials, where zero or more materials of the stack are work function materials and at least one material of the stack is a fill metal layer. Further materials/layers may be included next to the gate electrode for other purposes, such as to act as a diffusion barrier layer or/and an adhesion layer. The gate 745 may also include a gate insulator, part of which may be between the gate electrode and each semiconductor structure 735. The gate 745 may be electrically coupled to a power plane, ground plane, or signal plane for facilitating power supply or signal transmission for the transistor 705.

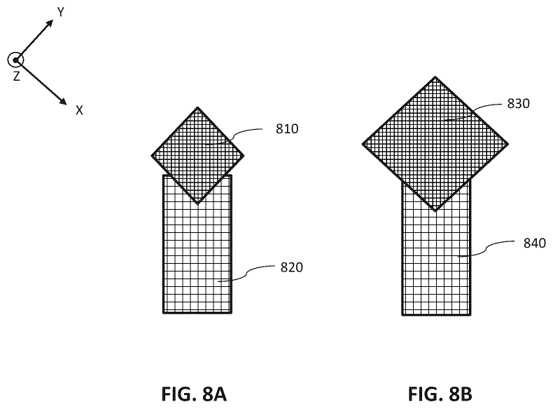

FIG. 8A illustrates semiconductor regions 810 and 820 of a transistor in a memory layer, according to some embodiments of the disclosure. The transistor is also referred to as a memory transistor. The memory layer may be an example of the memory layers 120 in FIG. 1, the memory layers 220 in FIG. 2, and the memory layers 620 and 630 in FIG. 3. FIG. 8B illustrates semiconductor regions 830 and 840 of a transistor in a logic layer, according to some embodiments of the disclosure. The transistor is also referred to as a logic transistor. The logic layer may be an example of the logic layer 110 in FIG. 1, the logic layer 210 in FIG. 2, and the logic layer 610 in FIG. 6. For the purpose of illustration, FIGS. 8A and 8B do not show other components of the transistors.

As shown in FIG. 8A, the semiconductor region 810 wraps around a portion of the semiconductor region 820. The semiconductor region 810 may be a source region or drain region of the memory transistor. The semiconductor region 820 may be a channel region of the memory transistor. In some embodiments, the semiconductor region 810 (or a semiconductor structure including the semiconductor region 810) may be a non-planar structure, such as a fin or nanoribbon. The semiconductor region 810 can be formed over the semiconductor region 820 through an epitaxy process or a layer transfer process.

In FIG. 8B, the semiconductor region 830 wraps around a portion of the semiconductor region 840. The semiconductor region 830 may be a source region or drain region of the logic transistor. The semiconductor region 840 may be a channel region of the logic transistor. In some embodiments, the semiconductor region 830 (or a semiconductor structure including the semiconductor region 830) may be a non-planar structure, such as a fin or nanoribbon. The semiconductor region 830 can be formed over the semiconductor region 840 through an epitaxy process or a layer transfer process.

In some embodiments, the cross section of the semiconductor region 810 in the X-Y plane is smaller than the cross section of the semiconductor region 830 in the X-Y plane. A width of the semiconductor region 820 along the X axis may be approximately 5% to approximately 50% larger than the width of the semiconductor region 810 along the X axis. For purpose of illustration, the cross section of the semiconductor region 810 in FIG. 8A and the cross section of the semiconductor region 830 in FIG. 8A each has a shape of a parallelogram with sharp corners. In other embodiments, the cross section of the semiconductor region 810 or the semiconductor region 830 can have other shapes, e.g., a curved shape with round corners.

In some embodiments, a transistor in a logic die may have more (e.g., approximately one to three times more) nanoribbon structures than a transistor in a memory die. The shape of the semiconductor region 810 may be different from the shape of the semiconductor region 820 in some embodiments. For instance, the semiconductor region 810 may be a fin, while the semiconductor region 820 may be a nanoribbon or nanowire.

FIG. 9A is an electric circuit diagram of an example memory cell 900, according to some embodiments of the present disclosure. FIG. 9B provides a top-down plan view of one example implementation of the memory cell 900, according to some embodiments of the present disclosure. In some embodiments, the memory cell 900 may be an SRAM cell used in a memory layer, such as the memory layer 220A in FIG. 2 or the memory layer 630 in FIG. 6. As shown in FIG. 9B, the memory cell 900 includes transistors M1-M4 for storing a bit value or a memory state (e.g., logic “1” or “0”) of the cell, and two access transistors, M5 and M6, for controlling access to the cell (e.g., access to write information to the cell or access to read information from the memory cell 900). The memory cell 900 is a 6-transistor (6T) memory cell. In other embodiments, the memory cell 900 may include a different number of transistors. Each of the transistors M1-M6 may have any transistor architecture (e.g., planar or non-planar, fin, nanoribbon, nanowire, etc.).

In the memory cell 900, each bit may be stored on four transistors (M1, M2, M3, M4) that form two cross-coupled inverters 920, each having an input 922 and an output 924. The first inverter 920-1 may be formed by an NMOS transistor M1 and a PMOS transistor M2, while the second inverter 920-2 may be formed by an NMOS transistor M3 and a PMOS transistor M4. As shown in FIG. 9B, the gate stack 912-1 of the transistor M1 may be coupled to the gate stack 912-2 of the transistor M2, and both of these gate stacks may be coupled to the input 922-1 of the first inverter 920-1. On the other hand, the first S/D region 914-1 of the transistor M1 may be coupled to the first S/D region 914-2 of the transistor M2, and both of these first S/D regions 914-1 and 914-2 may be coupled to the output 924-1 of the first inverter 920-1. Similarly, for the second inverter 320-2, the gate stack 912-3 of the transistor M3 may be coupled to the gate stack 912-4 of the transistor M4, and both of these gate stacks may be coupled to the input 922-2 of the second inverter 920-2, while the first S/D region 914-3 of the transistor M3 may be coupled to the first S/D region 914-4 of the transistor M4, and both of these first S/D regions 914-3 and 914-4 may be coupled to the output 924-2 of the second inverter 920-2. As also shown in FIG. 9B, when the transistors M1 and M3 are NMOS transistors and when the transistors M2 and M4 are PMOS transistors as illustrated in FIG. 9B, the second S/D regions 916-1 and 916-3 of the transistors M1 and M3 may be coupled to a ground voltage 932, while the second S/D regions 916-2 and 916-4 of the transistors M2 and M4 may be coupled to a supply voltage 934, e.g., VDD. In the embodiments of the memory cell 900 where the NMOS transistors shown in FIG. 9B are replaced with PMOS transistors and vice versa, the designation of the ground voltage 932 and the supply voltage 934 would be reversed as well, all of which embodiments being within the scope of the present disclosure.

The four transistors M1-M4 in such configuration form a stable storage cell for storing a bit value of 0 or 1. As further shown in FIG. 9B, two additional access transistors, M5 and M6, may serve to control the access to the storage cell of the transistors M1-M4 during read and write operations. As shown in FIG. 9B, the first S/D region 914-5 of the access transistor M5 may be coupled to the output 924-1 of the first inverter 920-1. Phrased differently, the first S/D region 914-5 of the access transistor M5 may be coupled to each of the first S/D region 914-1 of the transistor M1 and the first S/D region 914-2 of the transistor M2. The second S/D region 916-5 of the access transistor M5 may be coupled to a first bitline 940-1. Thus, each of the first S/D region 914-1 of the transistor M1 and the first S/D region 914-2 of the transistor M2 may be coupled to the first bitline 940-1 (e.g., via the access transistor M5). The gate 912-5 of the access transistor M5 may be coupled to a wordline 950.

As further shown in FIG. 9B, the first S/D region 914-6 of the access transistor M6 may be coupled to the output 924-2 of the second inverter 920-2. Phrased differently, the first S/D region 914-6 of the access transistor M6 may be coupled to each of the first S/D region 914-3 of the transistor M3 and the first S/D region 914-4 of the transistor M4. The second S/D region 916-6 of the access transistor M6 may be coupled to a second bitline 940-2. Thus, each of the first S/D region 914-3 of the transistor M3 and the first S/D region 914-4 of the transistor M4 may be coupled to the second bitline 940-2 (e.g., via the access transistor M6). The gate 912-6 of the access transistor M6 may be coupled to the wordline 950. Thus, the gates 912-5 and 912-6 of both of the access transistors M5 and M6 may be coupled to a single, shared, WL, the wordline 950.

As also shown in FIG. 9B, the input 922-1 of the first inverter 920-1 may be coupled to the first S/D region 914-6 of the access transistor M6, while the input 922-2 of the second inverter 920-2 may be coupled to the first S/D region 914-5 of the access transistor M5. In other words, each of the gate stack 912-1 of the transistor M1 and the gate stack 912-2 of the transistor M2 may be coupled to the first S/D region 914-6 of the access transistor M6, while each of the gate stack 912-3 of the transistor M3 and the gate stack 912-4 of the transistor M4 may be coupled to the first S/D region 914-5 of the access transistor M5. Phrased differently, each of the gate stack 912-1 of the transistor M1 and the gate stack 912-2 of the transistor M2 may be coupled to the second bitline 940-2 (e.g., via the access transistor M6), while each of the gate stack 912-3 of the transistor M3 and the gate stack 912-4 of the transistor M4 may be coupled to the first bitline 940-1 (e.g., via the access transistor M5).

The wordline 950 and the first and second bitlines 940 may be used together to read and program (i.e., write to) the memory cell 900. In particular, access to the cell may be enabled by the wordline 950 which controls the two access transistors M5 and M6 which, in turn, control whether the memory cell 900 should be connected to the bitlines 940-1 and 940-2. During operation of the memory cell 900, a signal on the first bitline 940-1 may be complementary to a signal on the second bitline 940-2. The two bitlines 940 may be used to transfer data for both read and write operations. In other embodiments of the memory cell 900, only a single bitline 940 may be used, instead of two bitlines 940-1 and 940-2, although having one signal bitline and one inverse, such as the two bitlines 940, may help improve noise margins.

During read accesses, the bitlines 940 are actively driven high and low by the inverters 920 in the memory cell 900. This may improve SRAM bandwidth compared to DRAM. The symmetric structure of the memory cell 900 also allows for differential signaling, which may provide an improvement in detecting small voltage swings. Another difference with DRAM that may contribute to making SRAM faster than DRAM is that commercial chips accept all address bits at a time. By comparison, commodity DRAMs may have the address multiplexed in two halves, i.e. higher bits followed by lower bits, over the same package pins in order to keep their size and cost down.

Each of the wordline 950 and the bitlines 940, as well as intermediate elements coupling these lines to various terminals described herein, may be formed of any suitable electrically conductive material, which may include an alloy or a stack of multiple electrically conductive materials. In some embodiments, such electrically conductive materials may include one or more metals or metal alloys, with metals such as ruthenium, palladium, platinum, cobalt, nickel, hafnium, zirconium, titanium, tantalum, and aluminum. In some embodiments, such electrically conductive materials may include one or more electrically conductive alloys oxides or carbides of one or more metals.

FIG. 9B provides a top-down plan view of one example implementation of a 6T memory cell, according to some embodiments of the present disclosure. FIG. 9B illustrates how the six transistors M1-M6 shown in FIG. 9B may be implemented. Several elements from FIG. 9B are labelled in FIG. 9B. For example, the transistors M1-M6 are labelled in FIG. 9B, with the approximate boundaries of the individual transistors shown in FIG. 9B with dashed rectangles. Certain elements, e.g., the specific S/D regions 914 and 916 and the gate stacks 912, are not labelled in FIG. 9B in order to not clutter the drawings.

FIG. 9B illustrates that transistors M1 and M5 may be provided along a first region of an N-type semiconductor 902, transistors M2 and M4 may each be provided along a respective first and second region of a P-type semiconductor 904, and the transistors M4 and M6 may be provided along a second region of the N-type semiconductor 902. Each of the regions of the N-type semiconductor 902 and P-type semiconductor 904 may be formed in a support structure (e.g., a substrate) or over a support structure, e.g., as a fin or nanoribbon. The N-type semiconductor 902 is suitable for forming transistors of a first type, e.g., NMOS transistors, while the P-type semiconductor 904 is suitable for forming transistors of a second type, e.g., PMOS transistors, thus realizing NMOS transistors M1, M3, M5, and M6, and PMOS transistors M2 and M4, as shown in FIG. 9B.

In the plan view shown in FIG. 9B, S/D contacts 906, gate electrodes 908, and interconnects 910 are formed over the N-type and P-type semiconductors 902 and 904, e.g., as layers processed over the N-type and P-type semiconductors 902 and 904. While not specifically shown in FIG. 9B, S/D regions may be formed under the S/D contacts 906, and gate dielectrics may be formed under the gate electrodes 908.

More specifically, a shared gate stack may be used to realize the gate stack 912-1 of the transistor M1 coupled to the gate stack 912-2 of the transistor M2. The shared gate stack is labelled 923-1 in FIG. 9B, representing a node that is the input 922-1 of the first inverter 920-1 of the memory cell 900. Similarly, a shared gate stack may be used to realize the gate stack 212-3 of the transistor M3 coupled to the gate stack 212-4 of the transistor M4 3. The shared gate stack is labelled 923-2 in FIG. 9B, representing a node that is the input 922-2 of the second inverter 920-2 of the memory cell 900.

As also shown in FIG. 9B, a first shared S/D contact may be used to realize the first S/D region 914-1 of the transistor M1 coupled to the first S/D region 914-2 of the transistor M2. The first shared S/D contact is labelled 925-1 in FIG. 9B, representing a node that is the output 924-1 of the first inverter 920-1 of the memory cell 900. Similarly, a second shared S/D contact may be used to realize the first S/D region 914-3 of the transistor M3 coupled to the first S/D region 914-4 of the transistor M4. The second shared S/D contact is labelled 925-2 in FIG. 9B, representing a node that is the output 924-2 of the second inverter 920-2 of the memory cell 900.

A first interconnect 910-1, shown in FIG. 9B, may then be used to couple the shared gate stack 923-1 of the first inverter 920-1 to the shared S/D contact 925-2 of the second inverter 920-2, thus realizing the coupling of the input 922-1 of the first inverter 920-1 to the output 924-2 of the second inverter 920-2, shown in FIG. 9B. Similarly, a second interconnect 910-2, shown in FIG. 9B, may then be used to couple the shared gate stack 923-2 of the second inverter 920-2 to the shared S/D contact 925-1 of the first inverter 920-1, thus realizing the coupling of the input 922-2 of the second inverter 920-2 to the output 924-1 of the first inverter 920-1, shown in FIG. 9B.

FIG. 9B further illustrates that, in a given memory cell 900, the first S/D region 914-5 of the transistor M5 may be shared with (e.g., be the same as) the first S/D region 914-1 of the transistor M1 (since both of these transistors are implemented in a single region of the N-type semiconductor 902). In addition, the first S/D region 914-3 of the transistor M3 may be shared with (e.g., be the same as) the first S/D region 914-6 of the transistor M6 (since both of these transistors are implemented in a single region of the N-type semiconductor 902).

Both of the second S/D region 916-1 of the transistor M1 and the second S/D region 916-3 of the transistor M3 may be coupled to the ground voltage 932, as was described with reference to FIG. 9B. Both of the second S/D region 916-2 of the transistor M2 and the second S/D region 916-4 of the transistor M4 may be coupled to the supply voltage 934, as was described with reference to FIG. 9B.

FIG. 10 is an electric circuit diagram of a memory array 1000, according to some embodiments of the present disclosure. The memory array 1000 is an array of memory cells 1005-11, 1005-12, 1005-21, and 1005-22 (collectively referred to as “memory cells 1005” or “memory cell 1005”), which are arranged in rows 1010-1 and 1010-2 (collectively referred to as “rows 1010” or “row 1010”) and columns 1012-1 and 1012-2 (collectively referred to as “columns 1012” or “column 1012”). Each memory cell 1005 is illustrated within one of the dashed boxes in FIG. 10. In some embodiments, the memory array 1000 may be in a DRAM array. The memory array 1000 may be in a memory layer, such as the memory layers 120 in FIG. 1, the memory layer 220B in FIG. 2, or the memory layer 620 in FIG. 6.

The memory array 1000 also includes three types of control lines: BLs 1040-1 and 1040-2 (collectively referred to as “BLs 1040” or “BL 1040”), WLs 1050-1 and 1050-2 (collectively referred to as “WLs 1050” or “WL 1050”), and platelines (PLs) 1060-1 and 1060-2 (collectively referred to as “PLs 1060” or “PL 1060”), which control the memory cells 1005. The memory cells 1005 in the row 1010-1 are coupled to the same BL 1040-1. The memory cells in the row 1010-1 are coupled to the same BL 1040-2. The memory cells in the column 1012-1 are coupled to the same WL 1050-2 and the same PL 1060-2. The memory cells in the column 1012-2 are coupled to the same WL 1050-1 and the same PL 1060-1. As is conventionally used in context of memory, the terms “row” and “column” do not reflect the, respectively, horizontal and vertical orientation on a page of a drawing illustrating a memory array but, instead, reflect how individual memory cells are addressed. Namely, memory cells 1005 sharing a single BL 1040 are said to be in the same row, while memory cells sharing a single WL 1050 and a single PL 1060 are said to be on the same column. In other embodiments, the memory array 1000 may include a different number of memory cells, BLs, WLs, or PLs. Furthermore, in other embodiments, the memory cells 1005 may be arranged in arrays in a manner other than what is shown in FIG. 10, e.g., in any suitable manner of arranging memory cells into arrays as known in the art, all of which being within the scope of the present disclosure.

A memory cell 1005 may store one bit of binary information. Each memory cell 1005 is a 1T-1X memory cell. The memory cell 1005 includes a memory element 1020 and an access transistor 1030. The memory element 1020 is configured to store signals. The memory element 1020 may have more than one states. The memory element 1020 having two states may be referred to as a binary memory element. In other embodiments, the memory element 1020 may have more than two states. In some embodiments, the memory element 1020 is a capacitor that can store electrical voltage signals, and the memory cell 1005 is a one-transistor one-capacitor (1T-1C) memory cell. In other embodiments, the memory element 1020 may be, for example, a ferroelectric memory element, a magnetic storage element, a resistor, or another transistor, coupled to the access transistor 1030. Also, the memory element 1020 may store signals other than electrical voltage signals.

The access transistor 1030 controls access to the memory cell 1005. For instance, the access transistor 1030 controls access to write information to the memory cell 1005, access to read information from the memory cell 1005, or both. The access transistor 1030 has a gate terminal, a source terminal, and a drain terminal, indicated in the example of FIG. 10 as terminals G, S, and D, respectively.

As shown in FIG. 10, the gate terminal of the access transistor 1030 is coupled to a WL 1050, one of the S/D terminals of the access transistor 1030 is coupled to a BL 1040, and the other one of the S/D terminals of the access transistor 1030 is coupled to a first terminal of the memory element 1020, e.g., a first electrode of a capacitor. As also shown in FIG. 10, the other terminal of the memory element 1020 may be coupled to a capacitor PL 1060. As is known in the art, WL, BL, and PL may be used together to read and program the memory element 1020. In some embodiments (e.g., embodiments where the access transistor 1030 is the vertical transistor 105), a portion of the BL 1040 may be a S/D region of the access transistor 1030. Another S/D region of the access transistor 1030 is coupled to the memory element 1020. Also, a portion of the WL 1050 may be a gate electrode of the access transistor 1030. Such vertical transistors can improve the memory cell density of the memory array 1000 so that more memory cells can be arranged in the available space of the memory array 1000.

Each of the BL 1040, the WL 1050, and the PL 1060, as well as intermediate elements coupling these lines to various terminals described herein, may be formed of any suitable electrically conductive material, which may include an alloy or a stack of multiple electrically conductive materials. In some embodiments, such electrically conductive materials may include one or more metals or metal alloys, with metals such as ruthenium, palladium, platinum, cobalt, nickel, hafnium, zirconium, titanium, tantalum, and aluminum. In some embodiments, such electrically conductive materials may include one or more electrically conductive alloys oxides or carbides of one or more metals.

In the embodiment of FIG. 10, a single PL 1060 is shared among multiple memory cells 1005 of a given row. The PLs 1060 are shared among the same memory cells 1005 among which the WL 1050 are shared. Such an arrangement where the PLs 1060 are shared among the same memory cells among which the WLs 1050 are shared may be described as an arrangement where the PLs 1060 are “parallel” to the WLs 1050. Each memory cell 1005 of the memory array 1000 where the PLs 1060 are parallel to the WLs 1050, e.g., as shown in FIG. 10, may then be addressed (e.g., to perform READ and WRITE operations) by using the WL 1050 and the PL 1060 corresponding to the column 1012 to which the memory cell 1005 belongs and by using the BL 1040 corresponding to the row 1010 to which the memory cell 1005 belongs.

It should be noted that, just as the horizontal and vertical orientations on a page of an electrical circuit diagram illustrating a memory array does imply functional division of memory cells into rows and columns as used in common language, the orientation of various elements on a page of an electrical circuit diagram illustrating a memory array does not imply that the same orientation is used for the actual physical layout of a memory array. For example, in an IC device implementing the memory array 1000, corresponding BLs 1040 and PLs 1060 (i.e., a pair of a BL 1040 and a PL 1060 coupled to a given column 1012) do not have to physically extend in a direction parallel to one another (although they may), or the WLs 1050 do not have to physically extend in a direction perpendicular to the BLs 1040 (although they may). In another example, in an IC device implementing the memory array 1000 as shown in FIG. 10, corresponding WLs 1050 and PLs 1060 (i.e., a pair of a WL 1050 and a PL 1060 coupled to a given column 1012) do not have to physically extend in a direction parallel to one another (although they may), or the WLs 1050 do not have to physically extend in a direction perpendicular to the BLs 1040 (although they may).

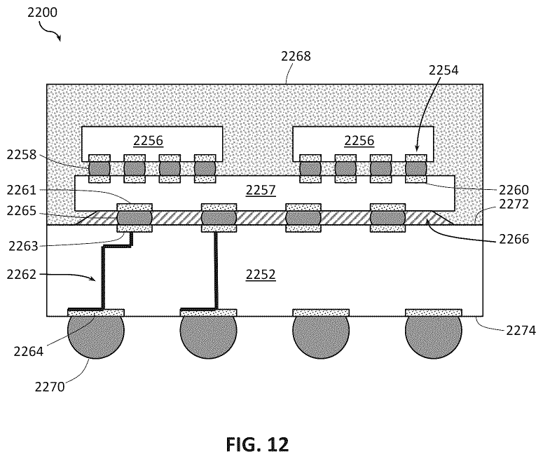

FIGS. 11A-11B are top views of a wafer 2000 and dies 2002 that may include one or more heterogeneous memory stacks with shared logic circuits, according to some embodiments of the disclosure. In some embodiments, the dies 2002 may be included in an IC package, according to some embodiments of the disclosure. For example, any of the dies 2002 may serve as any of the dies 2256 in an IC package 2200 shown in FIG. 12. The wafer 2000 may be composed of semiconductor material and may include one or more dies 2002 having IC devices formed on a surface of the wafer 2000. Each of the dies 2002 may be a repeating unit of a semiconductor product that includes any suitable IC (e.g., ICs with heterogeneous memory stacks with shared logic circuits as described herein, including the IC devices 100, 600, 700, and 800). After the fabrication of the semiconductor product is complete (e.g., after manufacture of heterogeneous memory stacks with shared logic circuits as described herein), the wafer 2000 may undergo a singulation process in which each of the dies 2002 is separated from one another to provide discrete “chips” of the semiconductor product. In particular, devices that include heterogeneous memory stacks with shared logic circuits as disclosed herein may take the form of the wafer 2000 (e.g., not singulated) or the form of the die 2002 (e.g., singulated). The die 2002 may include one or more diodes, one or more transistors (e.g., one or more III-N transistors as described herein) as well as, optionally, supporting circuitry to route electrical signals to the III-N diodes with n-doped wells and capping layers and III-N transistors, as well as any other IC components. In some embodiments, the wafer 2000 or the die 2002 may implement an electrostatic discharge (ESD) protection device, an radio frequency front-end device, a memory device (e.g., a SRAM device), a logic device (e.g., an AND, OR, NAND, or NOR gate), or any other suitable circuit element. Multiple ones of these devices may be combined on a single die 2002.

FIG. 12 is a side, cross-sectional view of an example IC package 2200 that may include one or more IC devices having heterogeneous memory stacks with shared logic circuits, according to some embodiments of the disclosure. In some embodiments, the IC package 2200 may be a system-in-package (SiP).

As shown in FIG. 12, the IC package 2200 may include a package substrate 2252. The package substrate 2252 may be formed of a dielectric material (e.g., a ceramic, a glass, a combination of organic and inorganic materials, a buildup film, an epoxy film having filler particles therein, etc., and may have embedded portions having different materials), and may have conductive pathways extending through the dielectric material between the face 2272 and the face 2274, or between different locations on the face 2272, and/or between different locations on the face 2274.

The package substrate 2252 may include conductive contacts 2263 that are coupled to conductive pathways 2262 through the package substrate 2252, allowing circuitry within the dies 2256 and/or the interposer 2257 to electrically couple to various ones of the conductive contacts 2264 (or to other devices included in the package substrate 2252, not shown).

The IC package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 12 are solder bumps, but any suitable first-level interconnects 2265 may be used. In some embodiments, no interposer 2257 may be included in the IC package 2200; instead, the dies 2256 may be coupled directly to the conductive contacts 2263 at the face 2272 by first-level interconnects 2265.

The IC package 2200 may include one or more dies 2256 coupled to the interposer 2257 via conductive contacts 2254 of the dies 2256, first-level interconnects 2258, and conductive contacts 2260 of the interposer 2257. The conductive contacts 2260 may be coupled to conductive pathways (not shown) through the interposer 2257, allowing circuitry within the dies 2256 to electrically couple to various ones of the conductive contacts 2261 (or to other devices included in the interposer 2257, not shown). The first-level interconnects 2258 illustrated in FIG. 12 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

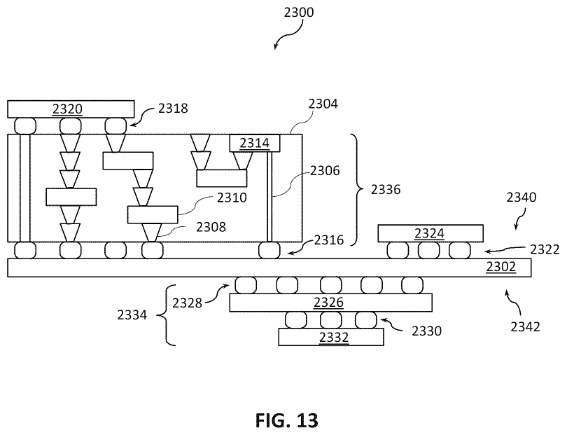

In some embodiments, an underfill material 2266 may be disposed between the package substrate 2252 and the interposer 2257 around the first-level interconnects 2265, and a mold compound 2268 may be disposed around the dies 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable. Second-level interconnects 2270 may be coupled to the conductive contacts 2264. The second-level interconnects 2270 illustrated in FIG. 12 are solder balls (e.g., for a ball grid array arrangement), but any suitable second-level interconnects 22770 may be used (e.g., pins in a pin grid array arrangement or lands in a land grid array arrangement). The second-level interconnects 2270 may be used to couple the IC package 2200 to another component, such as a circuit board (e.g., a motherboard), an interposer, or another IC package, as known in the art and as discussed below with reference to FIG. 13.

The dies 2256 may take the form of any of the embodiments of the die 2002 discussed herein and may include any of the embodiments of an IC device having one or more heterogeneous memory stacks with shared logic circuits. In embodiments in which the IC package 2200 includes multiple dies 2256, the IC package 2200 may be referred to as a multi-chip package. Importantly, even in such embodiments of an MCP implementation of the IC package 2200, one or more heterogeneous memory stacks with shared logic circuits may be provided in a single chip, in accordance with any of the embodiments described herein. The dies 2256 may include circuitry to perform any desired functionality. For example, one or more of the dies 2256 may be ESD protection dies, including one or more heterogeneous memory stacks with shared logic circuits as described herein, one or more of the dies 2256 may be logic dies (e.g., silicon-based dies), one or more of the dies 2256 may be memory dies (e.g., high bandwidth memory), etc. In some embodiments, any of the dies 2256 may include one or more heterogeneous memory stacks with shared logic circuits, e.g., as discussed above; in some embodiments, at least some of the dies 2256 may not include any III-N diodes with n-doped wells and capping layers.

The IC package 2200 illustrated in FIG. 12 may be a flip chip package, although other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fan-out (FO) package. Although two dies 2256 are illustrated in the IC package 2200 of FIG. 12, an IC package 2200 may include any desired number of the dies 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

FIG. 13 is a cross-sectional side view of an IC device assembly 2300 that may include components having heterogeneous memory stacks with shared logic circuits, according to some embodiments of the disclosure. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. In particular, any suitable ones of the components of the IC device assembly 2300 may include any of the IC devices implementing heterogeneous memory stacks with shared logic circuits in accordance with any of the embodiments disclosed herein; e.g., any of the IC packages discussed below with reference to the IC device assembly 2300 may take the form of any of the embodiments of the IC package 2200 discussed above with reference to FIG. 12 (e.g., may include one or more heterogeneous memory stacks with shared logic circuits in/on a die 2256).

In some embodiments, the circuit board 2302 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 13 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302, and may include solder balls (e.g., as shown in FIG. 13), male and female portions of a socket, an adhesive, an underfill material, and/or any other suitable electrical and/or mechanical coupling structure.

The package-on-interposer structure 2336 may include an IC package 2320 coupled to an interposer 2304 by coupling components 2318. The coupling components 2318 may take any suitable form for the application, such as the forms discussed above with reference to the coupling components 2316. The IC package 2320 may be or include, for example, a die (the die 2002 of FIG. 11B), an IC device (e.g., the IC device of FIGS. 1 and 2), or any other suitable component. In particular, the IC package 2320 may include one or more heterogeneous memory stacks with shared logic circuits as described herein. Although a single IC package 2320 is shown in FIG. 13, multiple IC packages may be coupled to the interposer 2304; indeed, additional interposers may be coupled to the interposer 2304. The interposer 2304 may provide an intervening substrate used to bridge the circuit board 2302 and the IC package 2320. Generally, the interposer 2304 may spread a connection to a wider pitch or reroute a connection to a different connection. For example, the interposer 2304 may couple the IC package 2320 (e.g., a die) to a BGA of the coupling components 2316 for coupling to the circuit board 2302. In the embodiment illustrated in FIG. 13, the IC package 2320 and the circuit board 2302 are attached to opposing sides of the interposer 2304; in other embodiments, the IC package 2320 and the circuit board 2302 may be attached to a same side of the interposer 2304. In some embodiments, three or more components may be interconnected by way of the interposer 2304.

The interposer 2304 may be formed of an epoxy resin, a fiberglass-reinforced epoxy resin, a ceramic material, or a polymer material such as polyimide. In some implementations, the interposer 2304 may be formed of alternate rigid or flexible materials that may include the same materials described above for use in a semiconductor substrate, such as Si, Ge, and other Group III-V and Group IV materials. The interposer 2304 may include metal interconnects 2308 and vias 2310, including but not limited to TSVs 2306. The interposer 2304 may further include embedded devices 2314, including both passive and active devices. Such devices may include, but are not limited to, capacitors, decoupling capacitors, resistors, inductors, fuses, diodes, transformers, sensors, ESD protection devices, and memory devices. More complex devices such as further RF devices, power amplifiers, power management devices, antennas, arrays, sensors, and microelectromechanical systems (MEMS) devices may also be formed on the interposer 2304. In some embodiments, the IC devices implementing one or more heterogeneous memory stacks with shared logic circuits as described herein may also be implemented in/on the interposer 2304. The package-on-interposer structure 2336 may take the form of any of the package-on-interposer structures known in the art.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 13 includes a package-on-package structure 2334 coupled to the second face 2342 of the circuit board 2302 by coupling components 2328. The package-on-package structure 2334 may include an IC package 2326 and an IC package 2332 coupled together by coupling components 2330 such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

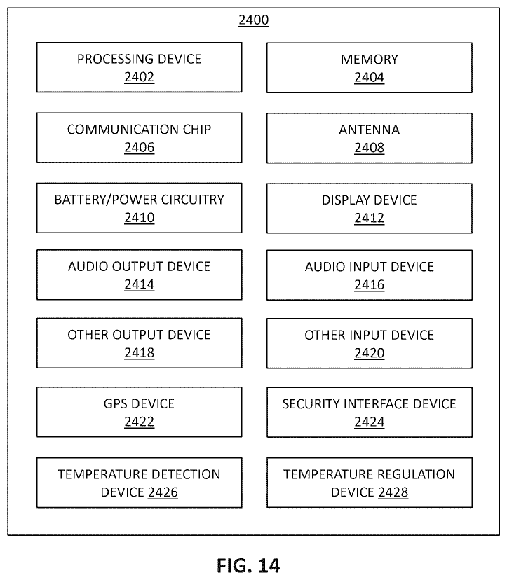

FIG. 14 is a block diagram of an example computing device 2400 that may include one or more components with heterogeneous memory stacks with shared logic circuits, according to some embodiments of the disclosure. For example, any suitable ones of the components of the computing device 2400 may include a die (e.g., the die 2002 (FIG. 11B)) having one or more heterogeneous memory stacks with shared logic circuits. Any one or more of the components of the computing device 2400 may include, or be included in, an IC package 2200 (FIG. 12). Any one or more of the components of the computing device 2400 may include, or be included in, an IC device assembly 2300 (FIG. 13).

A number of components are illustrated in FIG. 14 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single system-on-a-chip (SoC) die.

Additionally, in various embodiments, the computing device 2400 may not include one or more of the components illustrated in FIG. 14, but the computing device 2400 may include interface circuitry for coupling to the one or more components. For example, the computing device 2400 may not include a display device 2412, but may include display device interface circuitry (e.g., a connector and driver circuitry) to which a display device 2412 may be coupled. In another set of examples, the computing device 2400 may not include an audio input device 2416 or an audio output device 2414 but may include audio input or output device interface circuitry (e.g., connectors and supporting circuitry) to which an audio input device 2416 or audio output device 2414 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), nonvolatile memory (e.g., read-only memory (ROM)), flash memory, solid state memory, and/or a hard drive. In some embodiments, the memory 2404 may include memory that shares a die with the processing device 2402. This memory may be used as cache memory and may include embedded DRAM (eDRAM) or spin transfer torque magnetic random-access memory (STT-MRAM).

In some embodiments, the computing device 2400 may include a communication chip 2406 (e.g., one or more communication chips). For example, the communication chip 2406 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2406 may implement any of a number of wireless standards or protocols, including but not limited to Institute for Electrical and Electronic Engineers (IEEE) standards including Wi-Fi (IEEE 1402.11 family), IEEE 1402.16 standards (e.g., IEEE 1402.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1402.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.16 standards. The communication chip 2406 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2406 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2406 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2406 may operate in accordance with other wireless protocols in other embodiments. The computing device 2400 may include an antenna 2408 to facilitate wireless communications and/or to receive other wireless communications (such as AM or FM radio transmissions).

In some embodiments, the communication chip 2406 may manage wired communications, such as electrical, optical, or any other suitable communication protocols (e.g., the Ethernet). As noted above, the communication chip 2406 may include multiple communication chips. For instance, a first communication chip 2406 may be dedicated to shorter-range wireless communications such as Wi-Fi or Bluetooth, and a second communication chip 2406 may be dedicated to longer-range wireless communications such as global positioning system (GPS), EDGE, GPRS, CDMA, WiMAX, LTE, EV-DO, or others. In some embodiments, a first communication chip 2406 may be dedicated to wireless communications, and a second communication chip 2406 may be dedicated to wired communications.

The computing device 2400 may include a battery/power circuitry 2410. The battery/power circuitry 2410 may include one or more energy storage devices (e.g., batteries or capacitors) and/or circuitry for coupling components of the computing device 2400 to an energy source separate from the computing device 2400 (e.g., AC line power).

The computing device 2400 may include a display device 2412 (or corresponding interface circuitry, as discussed above). The display device 2412 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2414 (or corresponding interface circuitry, as discussed above). The audio output device 2414 may include any device that generates an audible indicator, such as speakers, headsets, or earbuds, for example.

The computing device 2400 may include an audio input device 2416 (or corresponding interface circuitry, as discussed above). The audio input device 2416 may include any device that generates a signal representative of a sound, such as microphones, microphone arrays, or digital instruments (e.g., instruments having a musical instrument digital interface (MIDI) output).

The computing device 2400 may include an other output device 2418 (or corresponding interface circuitry, as discussed above). Examples of the other output device 2418 may include an audio codec, a video codec, a printer, a wired or wireless transmitter for providing information to other devices, or an additional storage device.

The computing device 2400 may include an other input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may include a GPS device 2422 (or corresponding interface circuitry, as discussed above). The GPS device 2422 may be in communication with a satellite-based system and may receive a location of the computing device 2400, as known in the art.

The computing device 2400 may include a security interface device 2424. The security interface device 2424 may include any device that provides security features for the computing device 2400 or for any individual components therein (e.g., for the processing device 2402 or for the memory 2404). Examples of security features may include authorization, access to digital certificates, access to items in keychains, etc. Examples of the security interface device 2424 may include a software firewall, a hardware firewall, an antivirus, a content filtering device, or an intrusion detection device.

In some embodiments, the computing device 2400 may include a temperature detection device 2426 and a temperature regulation device 2428.

The temperature detection device 2426 may include any device capable of determining temperatures of the computing device 2400 or of any individual components therein (e.g., temperatures of the processing device 2402 or of the memory 2404). In various embodiments, the temperature detection device 2426 may be configured to determine temperatures of an object (e.g., the computing device 2400, components of the computing device 2400, devices coupled to the computing device, etc.), temperatures of an environment (e.g., a data center that includes, is controlled by, or otherwise associated with the computing device 2400), and so on. The temperature detection device 2426 may include one or more temperature sensors. Different temperature sensors of the temperature detection device 2426 may have different locations within and around the computing device 2400. A temperature sensor may generate data (e.g., digital data) representing detected temperatures and provide the data to another device, e.g., to the temperature regulation device 2428, the processing device 2402, the memory 2404, etc. In some embodiments, a temperature sensor of the temperature detection device 2426 may be turned on or off, e.g., by the processing device 2402 or an external system. The temperature sensor detects temperatures when it is on and does not detect temperatures when it is off. In other embodiments, a temperature sensor of the temperature detection device 2426 may detect temperatures continuously and automatically or detect temperatures at predefined times or at times triggered by an event associated with the computing device 2400 or any components therein.

The temperature regulation device 2428 may include any device configured to change (e.g., decrease) temperatures, e.g., based on one or more target temperatures and/or based on temperature measurements performed by the temperature detection device 2426. A target temperature may be a preferred temperature. A target temperature may depend on a setting in which the computing device 2400 operates. In some embodiments, the target temperature may be 200 Kelvin degrees or lower. In some embodiments, the target temperature may be 20 Kelvin degrees or lower, or 5 Kelvin degrees or lower. Target temperatures for different objects and different environments of, or associated with, the computing device 2400 can be different. In some embodiments, cooling provided by the temperature regulation device 2428 may be a multi-stage process with temperatures ranging from room temperature to 4K or lower.

In some embodiments, the temperature regulation device 2428 may include one or more cooling devices. Different cooling device may have different locations within and around the computing device 2400. A cooling device of the temperature regulation device 2428 may be associated with one or more temperature sensors of the temperature detection device 2426 and may be configured to operate based on temperatures detected the temperature sensors. For instance, a cooling device may be configured to determine whether a detected ambient temperature is above the target temperature or whether the detected ambient temperature is higher than the target temperature by a predetermined value or determine whether any other temperature-related condition associated with the temperature of the computing device 2400 is satisfied. In response to determining that one or more temperature-related condition associated with the temperature of the computing device 2400 are satisfied (e.g., in response to determining that the detected ambient temperature is above the target temperature), a cooling device may trigger its cooling mechanism and start to decrease the ambient temperature. Otherwise, the cooling device does not trigger any cooling. A cooling device of the temperature regulation device 2428 may operate with various cooling mechanisms, such as evaporation cooling, radiation cooling, conduction cooling, convection cooling, other cooling mechanisms, or any combination thereof. A cooling device of the temperature regulation device 2428 may include a cooling agent, such as a water, oil, liquid nitrogen, liquid helium, etc. In some embodiments, the temperature regulation device 2428 may be, for example, a dilution refrigerator, a helium-3 refrigerator, or a liquid helium refrigerator. In some embodiments, the temperature regulation device 2428 or any portions thereof (e.g., one or more of the individual cooling devices) may be connected to the computing device 2400 in close proximity (e.g., less than about 1 meter) or may be provided in a separate enclosure where a dedicated heat exchanger (e.g., a compressor, a heating, ventilation, and air conditioning (HVAC) system, liquid helium, liquid nitrogen, etc.) may reside.

By maintaining the target temperatures, the energy consumption of the computing device 2400 (or components thereof) can be reduced, while the computing efficiency may be improved. For example, when the computing device 2400 (or components thereof) operates at lower temperatures, energy dissipation (e.g., heat dissipation) may be reduced. Further, energy consumed by semiconductor components (e.g., energy needed for switching transistors of any of the components of the computing device 2400) can also be reduced. Various semiconductor materials may have lower resistivity and/or higher mobility at lower temperatures. That way, the electrical current per unit supply voltage may be increased by lowering temperatures. Conversely, for the same current that would be needed, the supply voltage may be lowered by lowering temperatures. As energy correlates to the supply voltage, the energy consumption of the semiconductor components may lower too. In some implementations, the energy savings due to reducing heat dissipation and reducing energy consumed by semiconductor components of the computing device or components thereof may outweigh (sometimes significantly outweigh) the costs associated with energy needed for cooling.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

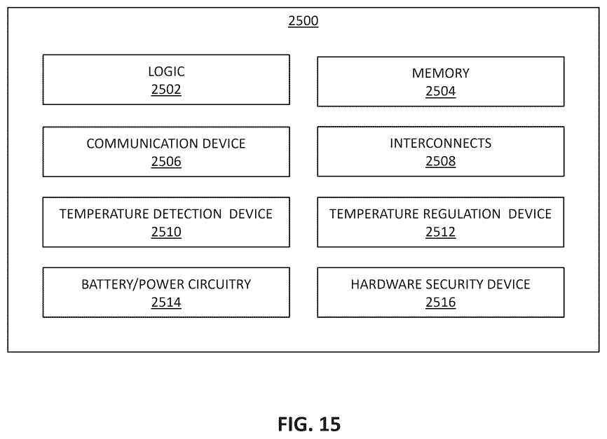

FIG. 15 is a block diagram of an example processing device 2500 that may include one or more heterogeneous memory stacks with shared logic circuits, according to some embodiments of the disclosure. For example, any suitable ones of the components of the processing device 2500 may include a die (e.g., the die 2002 (FIG. 11B)) having one or more heterogeneous memory stacks with shared logic circuits. Any one or more of the components of the processing device 2500 may include, or be included in, an IC package 2200 (FIG. 12). Any one or more of the components of the processing device 2500 may include, or be included in, an IC device assembly 2300 (FIG. 13). Any one or more of the components of the processing device 2500 may include, or be included in, a computing device 2400 (FIG. 14); for example, the processing device 2500 may be the processing device 2402 of the computing device 2400.

A number of components are illustrated in FIG. 15 as included in the processing device 2500, but any one or more of these components may be omitted or duplicated, as suitable for the application. In some embodiments, some or all of the components included in the processing device 2500 may be attached to one or more motherboards. In some embodiments, some or all of these components are fabricated on a single SoC die or coupled to a single support structure, e.g., to a single carrier substrate.

Additionally, in various embodiments, the processing device 2500 may not include one or more of the components illustrated in FIG. 15, but the processing device 2500 may include interface circuitry for coupling to the one or more components. For example, the processing device 2500 may not include a memory 2504, but may include display device interface circuitry (e.g., a connector and driver circuitry) to which a memory 2504 may be coupled.

The processing device 2500 may include logic circuitry 2502 (e.g., one or more circuits configured to implement logic/compute functionality). Examples of such circuits include ICs implementing one or more of input/output (I/O) functions, arithmetic operations, pipelining of data, etc.

In some embodiments, the logic circuitry 2502 may include one or more circuits responsible for read/write operations with respect to the data stored in the memory 2504. To that end, the logic circuitry 2502 may include one or more I/O ICs configured to control access to data stored in the memory 2504.

In some embodiments, the logic circuitry 2502 may include one or more high-performance compute dies, configured to perform various operations with respect to data stored in the memory 2504 (e.g., arithmetic and logic operations, pipelining of data from one or more memory dies of the memory 2504, and possibly also data from external devices/chips). In some embodiments, the logic circuitry 2502 may be configured to only control I/O access to data but not perform any operations on the data. In some embodiments, the logic circuitry 2502 may implement ICs configured to implement I/O control of data stored in the memory 2504, assemble data from the memory 2504 for transport (e.g., transport over a central bus) to devices/chips that are either internal or external to the processing device 2500, etc. In some embodiments, the logic circuitry 2502 may not be configured to perform any operations on the data besides I/O and assembling for transport to the memory 2504.

The processing device 2500 may include a memory 2504, which may include one or more ICs configure to implement memory circuitry (e.g., ICs implementing one or more of memory devices, memory arrays, control logic configured to control the memory devices and arrays, etc.). In some embodiments, the memory 2504 may be implemented substantially as described above with reference to the memory 2404 (FIG. 14). In some embodiments, the memory 2504 may be a designated device configured to provide storage functionality for the components of the processing device 2500 (i.e., local), while the memory 2404 may be configured to provide system-level storage functionality for the entire computing device 2400 (i.e., global). In some embodiments, the memory 2504 may include memory that shares a die with the logic circuitry 2502.

In some embodiments, the memory 2504 may include a flat memory (also sometimes referred to as a “flat hierarchy memory” or a “linear memory”) and, therefore, may also be referred to as a “basin memory.” As known in the art, a flat memory or a linear memory refers to a memory addressing paradigm in which memory may appear to the program as a single contiguous address space, where a processor can directly and linearly address all of the available memory locations without having to resort to memory segmentation or paging schemes. Thus, the memory implemented in the memory 2504 may be a memory that is not divided into hierarchical layer or levels in terms of access to its data.

In some embodiments, the memory 2504 may include a hierarchical memory. In this context, hierarchical memory refers to the concept of computer architecture where computer storage is separated into a hierarchy based on features of memory such as response time, complexity, capacity, performance, and controlling technology. Designing for high performance may require considering the restrictions of the memory hierarchy, i.e., the size and capabilities of each component. With hierarchical memory, each of the various memory components can be viewed as part of a hierarchy of memories (m1, m2, . . . , mn) in which each member mi is typically smaller and faster than the next highest member mi+1 of the hierarchy. To limit waiting by higher levels, a lower level of a hierarchical memory structure may respond by filling a buffer and then signaling for activating the transfer. For example, in some embodiments, the hierarchical memory implemented in the memory 2504 may be separated into four major storage levels: 1) internal storage (e.g., processor registers and cache), 2) main memory (e.g., the system RAM and controller cards), and 3) on-line mass storage (e.g., secondary storage), and 4) off-line bulk storage (e.g., tertiary, and off-line storage). However, as the number of levels in the memory hierarchy and the performance at each level has increased over time and is likely to continue to increase in the future, this example hierarchical division provides only one non-limiting example of how the memory 2504 may be arranged.

The processing device 2500 may include a communication device 2506, which may be implemented substantially as described above with reference to the communication chip 2406 (FIG. 14). In some embodiments, the communication device 2506 may be a designated device configured to provide communication functionality for the components of the processing device 2500 (i.e., local), while the communication chip 2406 may be configured to provide system-level communication functionality for the entire computing device 2400 (i.e., global).

The processing device 2500 may include interconnects 2508, which may include any element or device that includes an electrically conductive material for providing electrical connectivity to one or more components of, or associated with, a processing device 2500 or/and between various such components. Examples of the interconnects 2508 include conductive lines/wires (also sometimes referred to as “lines” or “metal lines” or “trenches”) and conductive vias (also sometimes referred to as “vias” or “metal vias”), metallization stacks, redistribution layers, metal-insulator-metal (MIM) structures, etc.

The processing device 2500 may include a temperature detection device 2510 which may be implemented substantially as described above with reference to the temperature detection device 2426 (FIG. 14) but configured to determine temperatures on a more local scale, i.e., of the processing device 2500 of components thereof. In some embodiments, the temperature detection device 2510 may be a designated device configured to provide temperature detection functionality for the components of the processing device 2500 (i.e., local), while the temperature detection device 2426 may be configured to provide system-level temperature detection functionality for the entire computing device 2400 (i.e., global).

The processing device 2500 may include a temperature regulation device 2512 which may be implemented substantially as described above with reference to the temperature regulation device 2428 (FIG. 14) but configured to regulate temperatures on a more local scale, i.e., of the processing device 2500 of components thereof. In some embodiments, the temperature regulation device 2512 may be a designated device configured to provide temperature regulation functionality for the components of the processing device 2500 (i.e., local), while the temperature regulation device 2428 may be configured to provide system-level temperature regulation functionality for the entire computing device 2400 (i.e., global).

The processing device 2500 may include a battery/power circuitry 2514 which may be implemented substantially as described above with reference to the battery/power circuitry 2410 (FIG. 14). In some embodiments, the battery/power circuitry 2514 may be a designated device configured to provide battery/power functionality for the components of the processing device 2500 (i.e., local), while the battery/power circuitry 2410 may be configured to provide system-level battery/power functionality for the entire computing device 2400 (i.e., global).

The processing device 2500 may include a hardware security device 2516 which may be implemented substantially as described above with reference to the security interface device 2424 (FIG. 14). In some embodiments, the hardware security device 2516 may be a physical computing device configured to safeguard and manage digital keys, perform encryption and decryption functions for digital signatures, authentication, and other cryptographic functions. In some embodiments, the hardware security device 2516 may include one or more secure cryptoprocessors chips.

The following paragraphs provide various examples of the embodiments disclosed herein.

Example 1 provides an IC device, including a first memory layer including a first group of conductive structures, the first memory layer having a first pitch that is a distance between two adjacent conductive structures in the first group; a second memory layer including a second group of conductive structures, the second memory layer having a second pitch that is a distance between two adjacent conductive structures in the second group; and a logic layer electrically coupled to the first memory layer and the second memory layer, in which the first pitch is different from the second pitch, and the second memory layer is between the first memory layer and the logic layer.

Example 2 provides the IC device according to example 1, in which the logic layer further includes a multiplexer, and the multiplexer is coupled to a conductive structure in the first group or a conductive structure in the second group.

Example 3 provides the IC device according to example 1 or 2, in which the first group of conductive structures includes one or more conductive structures of a capacitor in the first memory layer.

Example 4 provides the IC device according to example 3, in which the capacitor is coupled to a transistor in the first memory layer.

Example 5 provides the IC device according to any one of examples 1-4, further including a device region including a semiconductor material, in which the logic layer is between the second memory layer and the device region.

Example 6 provides the IC device according to any one of examples 1-5, in which the logic layer includes a pair of a P-type transistor and an N-type transistor.

Example 7 provides the IC device according to example 6, in which the P-type transistor is a PMOS transistor, and the N-type transistor is an NMOS transistor.

Example 8 provides an IC device, including a first layer including a first group of bitlines; a second layer including a second group of bitlines; and a third layer including a sense amplifier, in which the sense amplifier is coupled to one bitline in the first layer, and the sense amplifier is further coupled to two or more bitlines in the second layer.

Example 9 provides the IC device according to example 8, in which the first layer includes a SRAM cell, and the second layer includes a DRAM cell.

Example 10 provides the IC device according to example 8 or 9, in which the first layer includes a DRAM cell, and the second layer includes another DRAM cell.

Example 11 provides the IC device according to any one of examples 8-10, in which the first layer further includes a group of wordlines, and the third layer further includes a wordline driver coupled to a wordline in the first layer.

Example 12 provides the IC device according to example 11, in which the second layer further includes an additional wordline, and the wordline driver is separated from the additional wordline by an insulator.

Example 13 provides the IC device according to any one of examples 8-12, in which the second layer is between the first layer and the third layer.

Example 14 provides the IC device according to any one of examples 8-13, in which the third layer includes CMOS transistors.

Example 15 provides an IC device, including a first device region including a transistor; a conductive layer at a first side of the first device region; and a second device region at a second side of the first device region, the second side opposing the first side, the second device region including a transistor and a capacitor; and a third device region at the second side of the first device region, the third device region including a channel region of a P-type transistor and a channel region of a N-type transistor; and a multiplexer coupled to the transistor and at least one of the P-type transistor and the N-type transistor.

Example 16 provides the method according to example 15, further including a fourth device region at the second side of the first device region, in which the third device region is between the second device region and the fourth device region.

Example 17 provides the method according to example 16, in which the fourth device region is a semiconductor substrate.

Example 18 provides the method according to example 17, further including a conductive structure extending from the first device region to the third device region.

Example 19 provides the method according to example 18, in which the conductive structure is coupled to the conductive layer.

Example 20 provides the method according to any one of examples 15-19, in which the multiplexer is a 2:1 multiplexer, and a conductor pitch of the second device region is approximately half of a conductor pitch of the first device region.

Example 21 provides an IC package, including the IC device any one of examples 1-20; and a further IC component, coupled to the IC device.

Example 22 provides the IC package according to example 21, where the further IC component includes one of a package substrate, an interposer, or a further IC die.

Example 23 provides the IC package according to example 21 or 22, where the IC device may include, or be a part of, at least one of a memory device, a computing device, a wearable device, a handheld electronic device, and a wireless communications device.

Example 24 provides an electronic device, including a carrier substrate; and the IC package according to any one of examples 21-23, coupled to the carrier substrate.

Example 25 provides the electronic device according to example 24, where the carrier substrate is a motherboard.

Example 26 provides the electronic device according to example 24, where the carrier substrate is a PCB.

Example 27 provides the electronic device according to any one of examples 24-26, where the electronic device is a wearable electronic device or handheld electronic device.

Example 28 provides the electronic device according to any one of examples 24-27, where the electronic device further includes one or more communication chips and an antenna.

Example 29 provides the electronic device according to any one of examples 24-28, where the electronic device is an RF transceiver.

Example 30 provides the electronic device according to any one of examples 24-28, where the electronic device is one of a switch, a power amplifier, a low-noise amplifier, a filter, a filter bank, a duplexer, an upconverter, or a downconverter of an RF communications device, e.g., of an RF transceiver.

Example 31 provides the electronic device according to any one of examples 24-30, where the electronic device is a computing device.

Example 32 provides the electronic device according to any one of examples 24-31, where the electronic device is included in a base station of a wireless communication system.

Example 33 provides the electronic device according to any one of examples 24-31, where the electronic device is included in a user equipment device of a wireless communication system.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) device, comprising:
a first memory layer comprising a first group of conductive structures, the first memory layer having a first pitch that is a distance between two adjacent conductive structures in the first group;
a second memory layer comprising a second group of conductive structures, the second memory layer having a second pitch that is a distance between two adjacent conductive structures in the second group; and
a logic layer electrically coupled to the first memory layer and the second memory layer,
wherein the first pitch is different from the second pitch, and the second memory layer is between the first memory layer and the logic layer.

2. The IC device according to claim 1, wherein the logic layer further comprises a multiplexer, and the multiplexer is coupled to a conductive structure in the first group or a conductive structure in the second group.

3. The IC device according to claim 1, wherein the first group of conductive structures comprises one or more conductive structures of a capacitor in the first memory layer.

4. The IC device according to claim 3, wherein the capacitor is coupled to a transistor in the first memory layer.

5. The IC device according to claim 1, further comprising:
a device region comprising a semiconductor material, wherein the logic layer is between the second memory layer and the device region.

6. The IC device according to claim 1, wherein the logic layer comprises a pair of a P-type transistor and an N-type transistor.

7. The IC device according to claim 6, wherein the P-type transistor is a P-channel metal oxide semiconductor transistor, and the N-type transistor is an N-channel metal oxide semiconductor transistor.

8. An integrated circuit (IC) device, comprising:
a first layer comprising a first group of bitlines;
a second layer comprising a second group of bitlines; and
a third layer comprising a sense amplifier, wherein the sense amplifier is coupled to one bitline in the first layer, and the sense amplifier is further coupled to two or more bitlines in the second layer.

9. The IC device according to claim 8, wherein the first layer comprises a static random-access memory cell, and the second layer comprises a dynamic random-access memory cell.

10. The IC device according to claim 8, wherein the first layer comprises a dynamic random-access memory cell, and the second layer comprises another dynamic random-access memory cell.

11. The IC device according to claim 8, wherein the first layer further comprises a group of wordlines, and the third layer further comprises a wordline driver coupled to a wordline in the first layer.

12. The IC device according to claim 11, wherein the second layer further comprises an additional wordline, and the wordline driver is separated from the additional wordline by an insulator.

13. The IC device according to claim 8, wherein the second layer is between the first layer and the third layer.

14. The IC device according to claim 8, wherein the third layer comprises complementary metal-oxide-semiconductor transistors.

15. An integrated circuit (IC) device, comprising:
a first device region comprising a semiconductor structure of a transistor;
a conductive layer at a first side of the first device region; and
a second device region at a second side of the first device region, the second side opposing the first side, the second device region comprising a transistor and a capacitor; and
a third device region at the second side of the first device region, the third device region comprising a channel region of a P-type transistor and a channel region of a N-type transistor; and
a multiplexer coupled to the transistor and at least one of the P-type transistor and the N-type transistor.

16. The IC device according to claim 15, further comprising:
a fourth device region at the second side of the first device region, wherein the third device region is between the second device region and the fourth device region.

17. The IC device according to claim 16, wherein the fourth device region is a semiconductor substrate.

18. The IC device according to claim 17, further comprising:
a conductive structure extending from the first device region to the third device region.

19. The IC device according to claim 18, wherein the conductive structure is coupled to the conductive layer.

20. The IC device according to claim 15, wherein the multiplexer is a 2:1 multiplexer, and a conductor pitch of the second device region is approximately half of a conductor pitch of the first device region.
